(19) United States
(12) Patent Application Publication
(10) Pub. No.: US 2024/0055275 A1
(43) Pub. Date: Feb. 15, 2024

(54) MOVING BLADE CAVITY TECHNOLOGY FOR HIGH DENSE UNITS PER STRIP DESIGN

(71) Applicant: Texas Instruments Incorporated, Dallas, TX (US)

(72) Inventors: Makoto Shibuya, Tokyo (JP); Han Meng @ Eugene Lee, Melaka (MY)

(21) Appl. No.: 17/887,595

(22) Filed: Aug. 15, 2022

(51) Int. Cl. H01L 21/56; H01L 23/31; B29C 45/14; B29C 69/00; B29C 45/26

(52) U.S. Cl. CPC H01L 21/561; H01L 23/3107; H01L 21/565; B29C 45/14819; B29C 69/001; B29C 45/26; H01L 24/48

(57) ABSTRACT

A method of fabricating an electronic device includes injecting molding compound into respective column cavities of a mold to enclose semiconductor dies of respective unit regions of a lead frame panel in the respective column cavities and inserting a blade into the respective column cavities of the mold between adjacent unit regions of the lead frame panel to separate individual molded package structures in the respective column cavities of the mold along a column direction.

### BACKGROUND

Interdigitated lead frames have columns of devices offset from neighboring columns and can help increase device density during integrated circuit manufacturing. Separating molded packages from an interdigitated lead frame pane, however, is difficult due to the offset positioning of device packages in the panel. Saw cutting along a row direction can be used in combination with prior column alignment for pitch correction to rearrange the units from a zigzag arrangement in a straight line followed by saw cutting, but this approach increases manufacturing cost and complexity. Laser cutting can be used for package separation without prior pitch correction, but this is time consuming compare with straight cutting.

### SUMMARY

In one aspect, a method includes injecting molding compound into respective column cavities of a mold to enclose semiconductor dies of respective unit regions of a lead frame panel in the respective column cavities and inserting a blade into the respective column cavities of the mold between adjacent unit regions of the lead frame panel to separate individual molded package structures in the respective column cavities of the mold along a column direction.

In another aspect, an apparatus includes a mold having column cavities and blade channels. The column cavities are spaced apart from one another along a first direction, the column cavities extend along a second direction, and the blade channels extend into a respective column cavity along a third direction. Blades are positioned in respective blade channels of the mold and an actuator inserts portions of the blades from the respective blade channels into the respective column cavities toward a lead frame panel along the third direction to separate individual molded package structures between adjacent unit regions of the lead frame panel in the respective column cavities along the second direction.

In a further aspect, an electronic device includes a molded package structure and conductive leads. The molded package structure has six sides with third and fourth sides spaced apart from the first side along a first direction, fifth and sixth sides spaced apart one another along a second direction, and first and second sides spaced apart from one another along a third direction. The conductive leads extend out of the third and fourth sides of the molded package structure. The electronic device includes one of a protrusion extending along the first direction out of one of the third and fourth sides and extending along the third direction from the first side to the second side, and an indent extending along the second direction into one of the fifth and sixth sides and extending along the third direction from the first side to the second side.

### BRIEF DESCRIPTION OF THE DRAWINGS

FIG. 1 is a top perspective view of an electronic device with ends formed by blade insertion during package molding according to one aspect.

FIG. 1A is a top perspective view of another example of the electronic device with end indents formed by ribbed blades inserted during package molding.

FIG. 1B is a top perspective view of another example of the electronic device with end indents formed by ribbed blades inserted during package molding as well as side protrusions formed during package molding.

FIG. 1C is a top perspective view of another example of the electronic device side protrusions formed during package molding.

FIG. 2 is a flow diagram of a method of fabricating an electronic device according to another aspect.

FIG. 3 is a partial top plan view of an interdigitated lead frame panel or strip with staggered or offset adjacent columns having multiple unit regions for concurrent fabrication of multiple electronic devices.

FIG. 4 is a partial top plan view of the lead frame panel undergoing die attach processing.

FIG. 4A a is a partial sectional side elevation view taken along line 4A-4A of FIG. 4.

FIG. 5 is a partial top plan view of the lead frame panel undergoing electrical connection processing using bond wires.

FIG. 5A a is a partial sectional side elevation view taken along line 5A-5A of FIG. 5.

FIG. 6 is a partial top plan view of the lead frame panel undergoing molding processing in a mold apparatus prior to molding compound injection.

FIG. 6A is a partial sectional side elevation view taken along line 6A-6A of FIG. 6 with movable blades in a retracted position prior to molding compound injection.

FIG. 6B is a partial sectional side elevation view taken along line 6B-6B of FIG. 6 showing further details of a portion of a mold apparatus with the movable blades in the retracted position prior to mold closure.

FIG. 6C is a partial exploded view showing further details of the mold apparatus of FIGS. 6-6B.

FIG. 6D is a partial sectional side elevation view taken along line 6D-6D of FIG. 6 showing a portion of the mold apparatus in a closed position with the movable blades in the retracted position prior to insertion into column cavities of upper and lower mold portions.

FIG. 6E is a partial sectional side elevation view taken along line 6E-6E of FIG. 6 showing the mold apparatus in the closed position with the movable blades in the retracted position prior to molding compound injection.

FIG. 6F is a partial top perspective view showing the mold apparatus in the closed position with the movable blades in the retracted position prior to molding compound injection.

FIG. 7 is a partial top plan view of the lead frame panel and mold apparatus during molding compound injection.

FIG. 7A is a partial sectional side elevation view taken along line 7A-7A of FIG. 7 with column cavities of the mold substantially filled with molding compound and the movable blades in the retracted position.

FIG. 7B is a partial sectional side elevation view taken along line 7B-7B of FIG. 7 showing a portion of a mold apparatus with the column cavities substantially filled with molding compound and the movable blades in the retracted position.

FIG. 7C is a partial top perspective view of two adjacent column cavities filled with molding compound prior to blade insertion into the column cavities of the mold apparatus.

FIG. 8 is a partial top plan view of the lead frame panel and mold apparatus after molding compound injection with the movable blades in an inserted or extended position.

FIG. 8A is a partial sectional side elevation view taken along line 8A-8A of FIG. 8 with column cavities of the mold substantially filled with molding compound and the movable blades in the inserted position.

FIG. 8B is a partial sectional side elevation view taken along line 8B-8B of FIG. 8 showing a portion of the mold apparatus with the column cavities substantially filled with molding compound and the movable blades in the inserted position.

FIG. 8C is a partial top perspective view showing the mold apparatus in the closed position with the movable blades in the inserted position.

FIG. 8D is a partial top perspective view of two adjacent column cavities with multiple individual molded package structures in the respective column cavities along a column direction.

FIG. 8E is a partial sectional side elevation view taken along line 8E-8E of FIG. 8 showing the movable blades in the inserted position to separate molded package structures in the column cavity along the column direction.

FIG. 9 is a partial top plan view of the lead frame panel and mold apparatus after molding compound injection with the movable blades in an inserted or extended position.

FIG. 9A is a partial sectional side elevation view taken along line 9A-9A of FIG. 9 with the mold apparatus in the open position and the movable blades in the retracted position.

FIG. 9B is a partial sectional side elevation view taken along line 9B-9B of FIG. 9 showing a portion of the mold apparatus in the open position and the movable blades in the retracted position.

FIG. 10 is a partial sectional side elevation view of a portion of the lead frame panel with separated molded package structures undergoing lead trim processing.

FIG. 11 is a partial sectional side elevation view of a portion of the lead frame panel with separated molded package structures undergoing lead form processing.

FIG. 12 is a partial top perspective view of a further example configuration of a portion of the mold apparatus with configurable blade insertion locations to facilitate use of a single mold with multiple pin count packaged electronic device designs in a closed position with the movable blades in the retracted position during molding compound injection prior to blade insertion.

FIG. 12A is a partial top perspective view of two example columns of the lead frame panel during molding compound injection prior to blade insertion.

FIG. 13 is a partial top perspective view of the further example configuration of a portion of the mold apparatus with configurable blade insertion locations in the closed position with the movable blades in the inserted position with separated individual molded package structures in each column cavity.

FIG. 13A is a partial top perspective view of two example columns of the lead frame panel with separated individual molded package structures in each column cavity.

FIG. 14 shows a simplified partial top plan view of another example configuration of the mold apparatus using high strength mold blades with ribs on tapered opposite sides creating indents in the ends of the separated molded package structure.

FIG. 15 shows a simplified partial top plan view of an example configuration of the mold apparatus using tapered mold blades to separate individual molded package structures in the column cavities.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating.

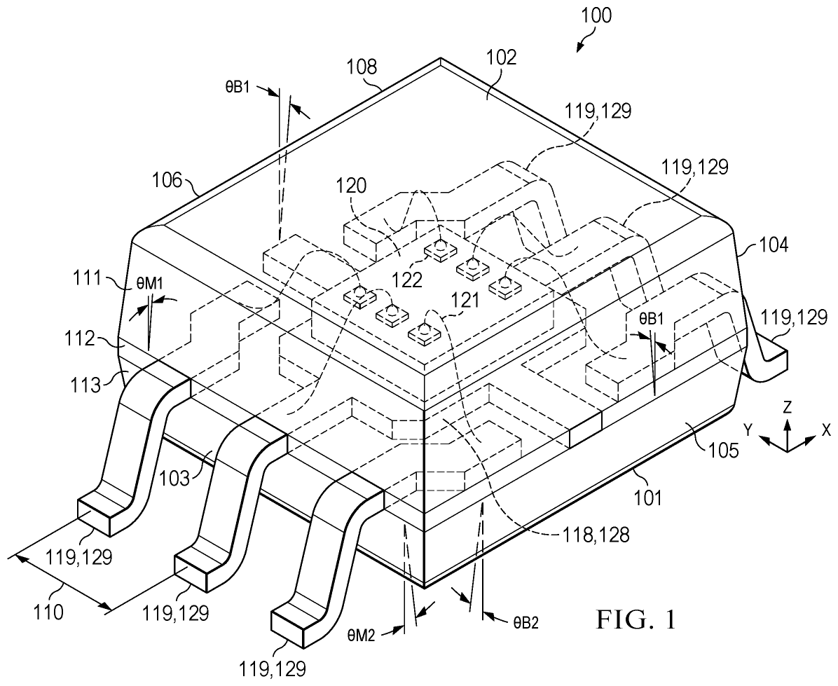

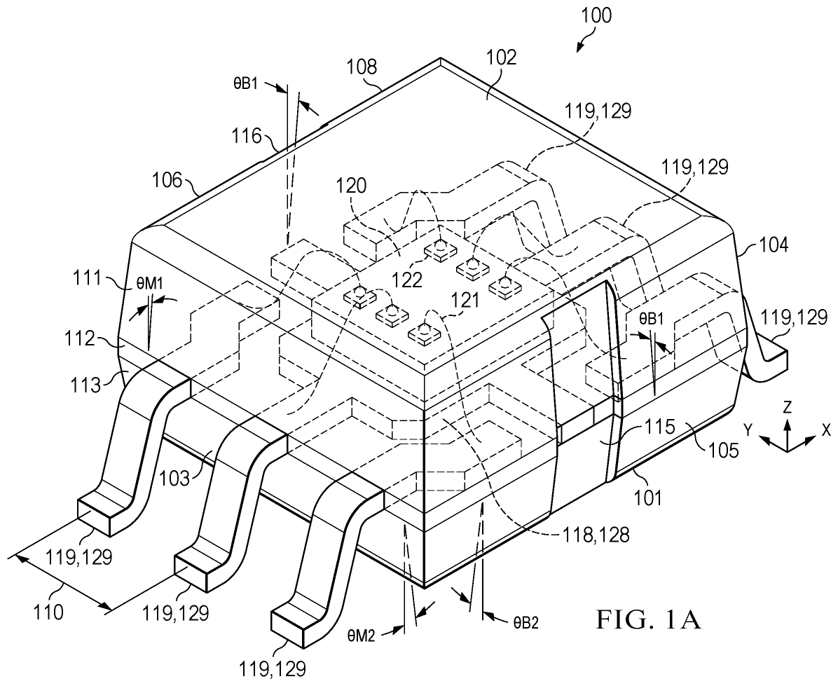

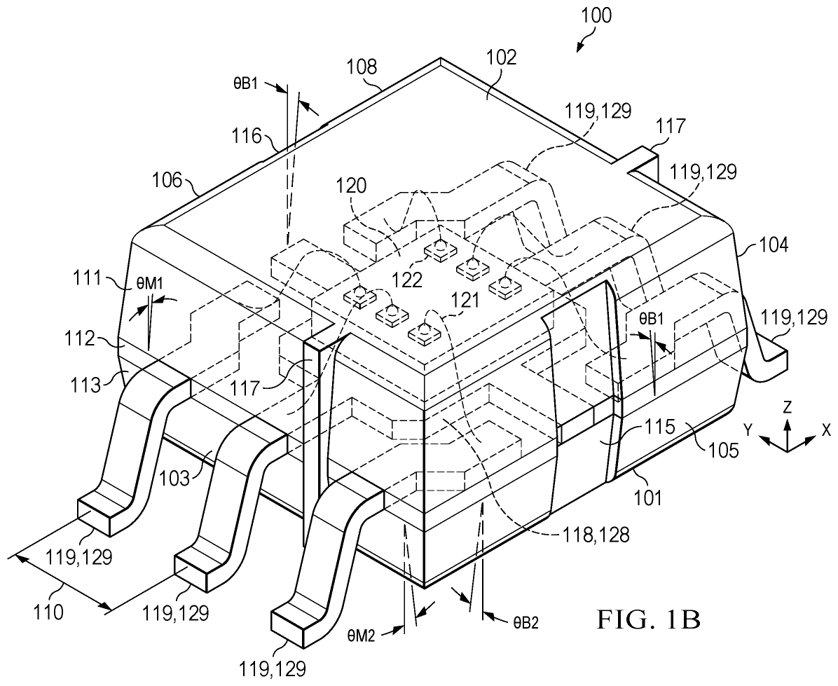

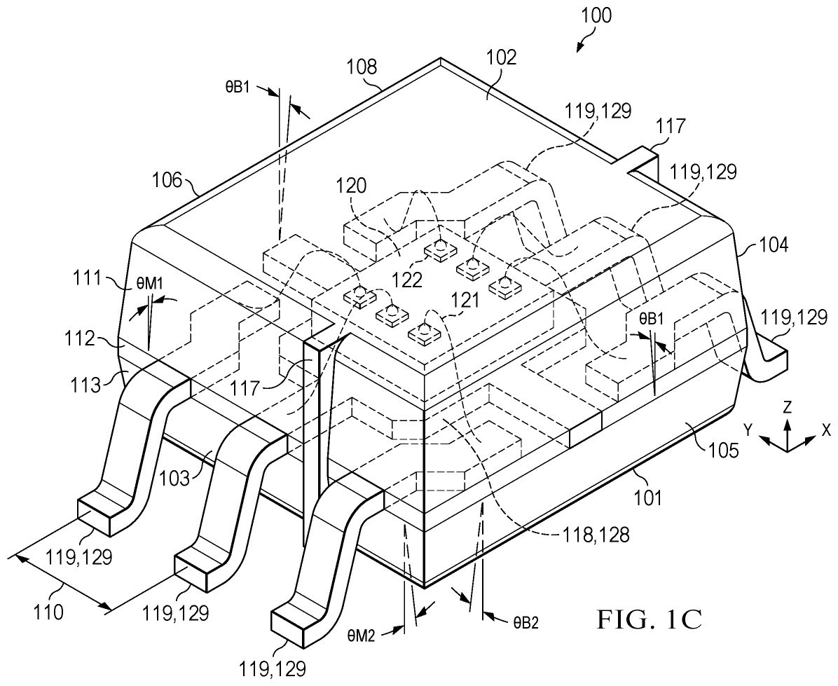

Referring initially to FIGS. 1-1C, FIG. 1 shows an electronic device 100 with a molded package structure 108 having a first side 101, a second side 102, a third side 103, a fourth side 104, a fifth side 105, and a sixth side 106. The respective third and fourth sides 103 and 104 are spaced apart from one another along a first direction (e.g., the X direction in the illustrated device orientation) and the respective fifth and sixth sides 105 and 106 are spaced apart from one another along a second direction (e.g., Y) that is perpendicular to the first direction X. The respective first and second sides 101 and 102 are spaced apart from one another along a third direction (e.g., Z) that is perpendicular to the first and second directions X and Y. The example device includes conductive leads labelled 119, 129 in FIGS. 1-1C. The leads 119, 129 extend out of the respective third and fourth sides 103 and 104 of the molded package structure 108. The illustrated leads 119, 129 are gullwing leads positioned at a pitch spacing distance 110 from neighboring ones of the leads 119, 129 on the third and fourth sides 103 and 104, respectively. In other implementations, different numbers of leads and/or different lead shapes can be used, for example “J” leads (not shown). In addition, these or other implementations can include leads on one or both of the other lateral sides 105 and/or 106 (not shown). The leads 119, 129 in one example are a conductive metal, such as aluminum or copper or alloys thereof.

The respective fifth and sixth sides 105 and 106 form ends of an elongated rectangular molded package structure 108, and the sides 105 and 106 are formed by blade insertion during package molding as further described below. The example package structure 108 is formed by a molding process that uses upper and lower mold portions. The long third and fourth sides 103 and 104 have upper portions 111 formed by an upper mold cavity with a first angle θM1 to the third direction Z, as well as a middle or second portion 112 and a lower third portion 113 formed by a lower mold cavity with a second angle θM2 to the third direction Z.

The shorter ends of the package structure 108 formed by the fifth and sixth sides 105 and 106 are created during molding processing by upper and lower blades inserted into column cavities of the mold apparatus. As shown in FIG. 1, the fifth side 105 has an upper portion at a first blade angle θB1 to the third direction Z, a middle portion, and a lower portion at a second blade angle θB2 to the third direction Z, and the sixth side 106 has similar portions at the respective first and second blade angles θB1 and θB2.

The electronic device 100 includes a semiconductor die 120 mounted on a die attach pad labeled 118, 128 in FIGS. 1-1C. The semiconductor die 120 includes conductive features, such as copper or aluminum bond pads 122, as well as bond wires 121 to form electrical connections (not shown) between respective bond pads 122 and leads 119, 129 or other components within the molded package structure 108 (not shown).

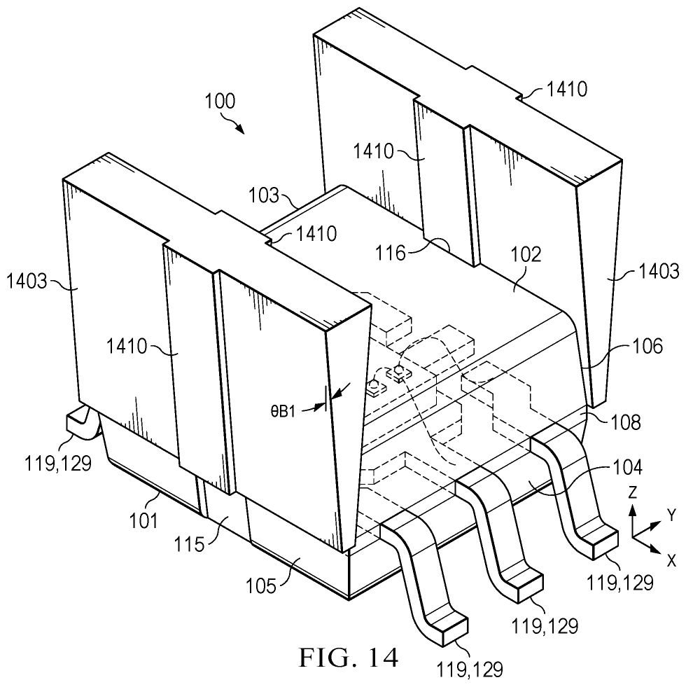

FIGS. 1A-1C show further examples of the electronic device 100 including protrusions and/or indents. FIG. 1A shows an example of the electronic device 100 with end indents 115 and 116 in the respective fifth and sixth sides 105 and 106. The indents 115 and 116 in this example are formed by upper and lower ribbed blades inserted during package molding, as described further below in connection with FIG. 14. In another example, only one of the sides 105 and 106 includes an indent. In the illustrated example, the indent 115 extends along the second direction Y into the fifth side 105 and extends along the third direction Z from the first side 101 to the second side 102. In this example, moreover, the indent 116 extends along the second direction Y into the sixth side 106 and extends along the third direction Z from the first side 101 to the second side 102.

FIG. 1B shows another example of the electronic device 100 with end indents 115 and 116 extending into the respective sides 105 and 106, which are formed by ribbed blades inserted during package molding as discussed above in connection with FIG. 1A. In addition, the electronic device 100 and FIG. 1B includes side protrusions 117 that extend along the first direction X out of the third and fourth sides 103 and 104. In another example, only one of the sides 103 or 104 includes an outwardly extending protrusion 117. The protrusions 117 each extend along the third direction Z from the first side 101 to the second side 102 in the illustrated example.

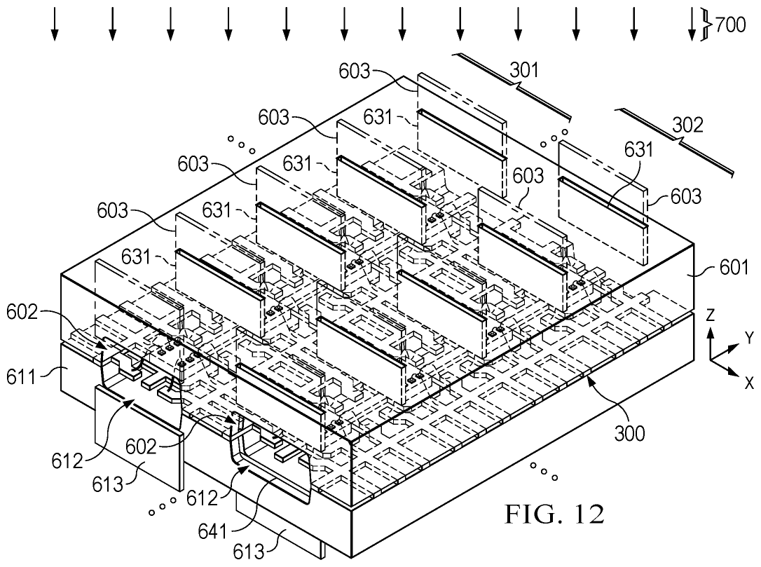

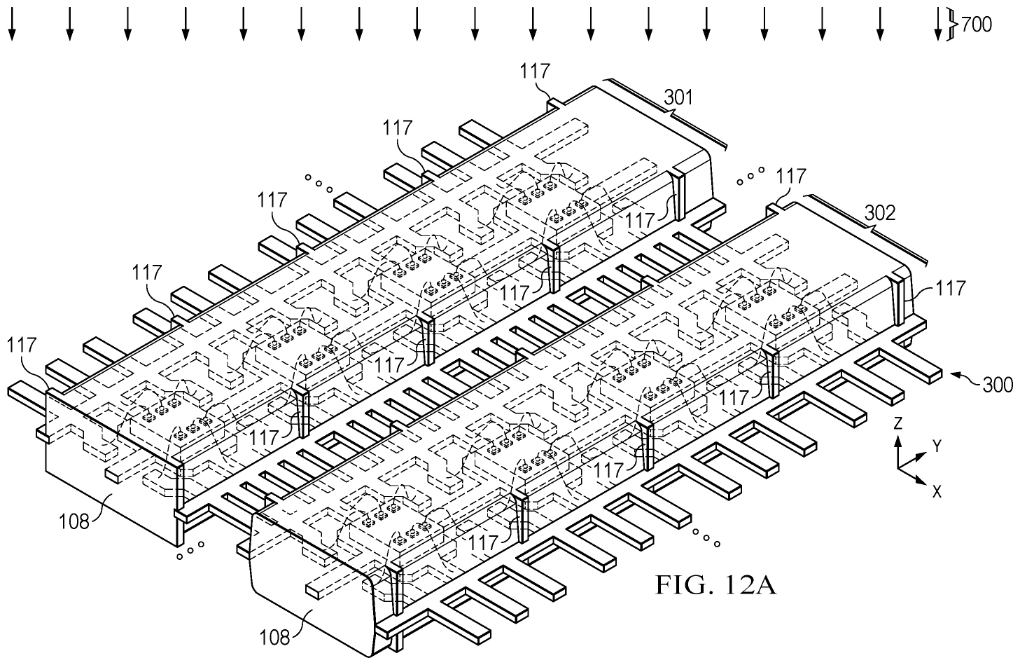

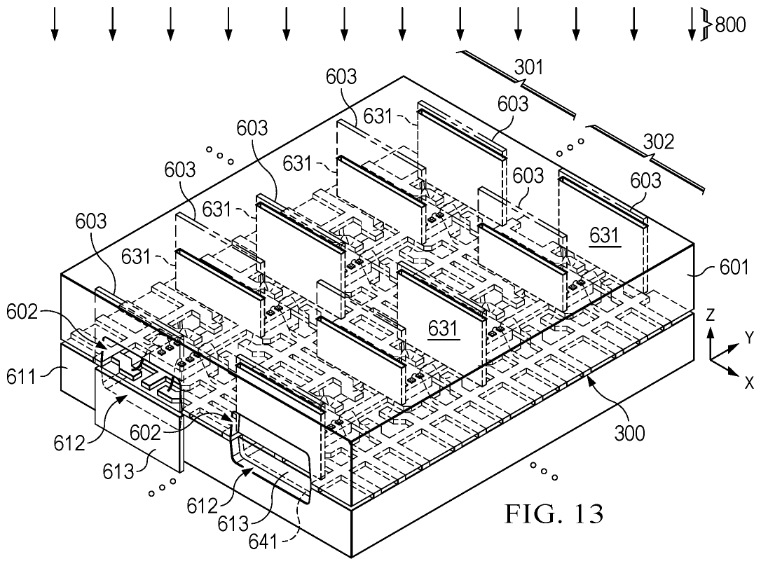

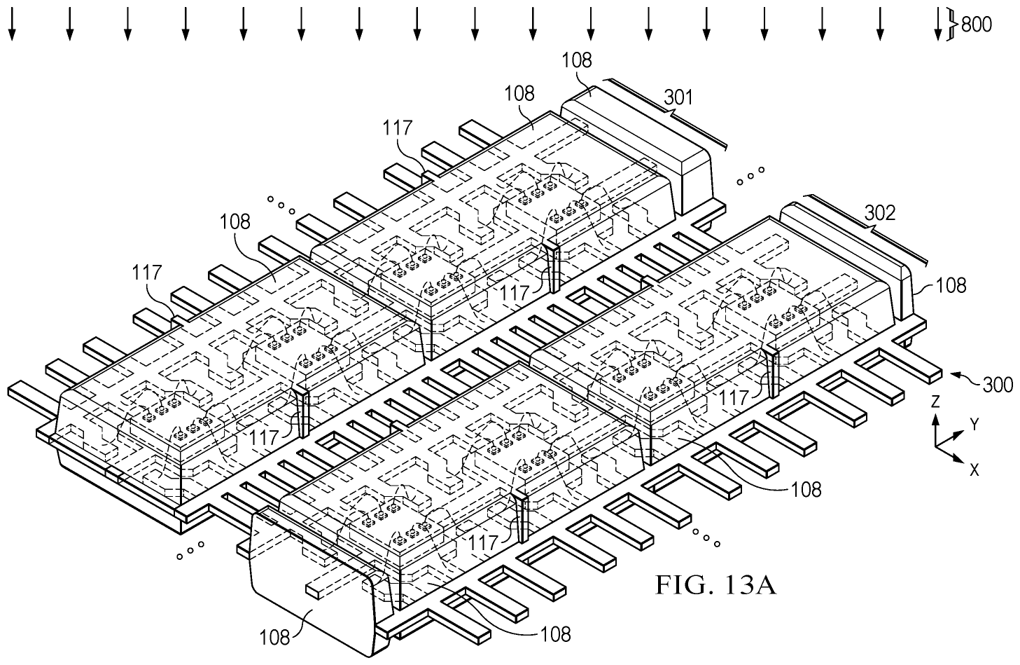

The protrusions 117 are formed during package molding using a mold apparatus that is configurable to selectively insert fewer than all movable blades into the column cavity of the mold as discussed further below in connection with FIGS. 12 and 13. The protrusions 117 in the example of FIG. 1B are formed during mold filling in a position along the second direction Y (e.g., referred to as a column direction with respect to the molding processing and apparatus) that has a movable blade channel, but no blade is inserted in that blade channel. In this regard, the provision of blade channels in a variety of positions along the second direction Y allow selective insertion or non-insertion of movable blades to allow the mold apparatus to be used for a variety of different package sizes and configurations. As shown in the example of FIG. 1B, the non-insertion of a movable blade (e.g., or upper and lower blades) at a particular blade channel position along the second direction Y creates the protrusions 117 during molding operations.

FIG. 1C shows another example of the electronic device 100 with the above-described side protrusions 117 formed during package molding, which extend outward along the first direction X from the respective third and fourth sides 103 and 104 as described above in connection with FIG. 1B. In this example, the fifth and sixth sides 105 and 106 at the ends of the molded package structure 108 are formed by inserted blades during mold processing, where the inserted blades do not include ribbed features and the sides 105 and 106 do not include indents as was the case in the examples of FIGS. 1A and 1B above.

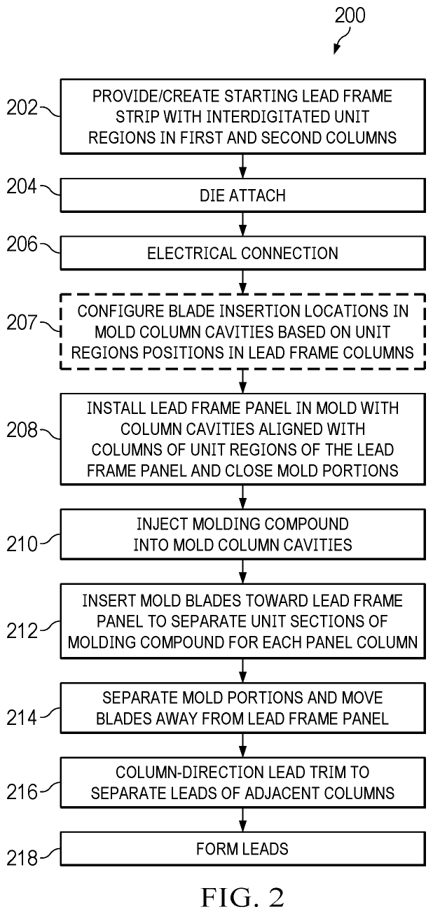

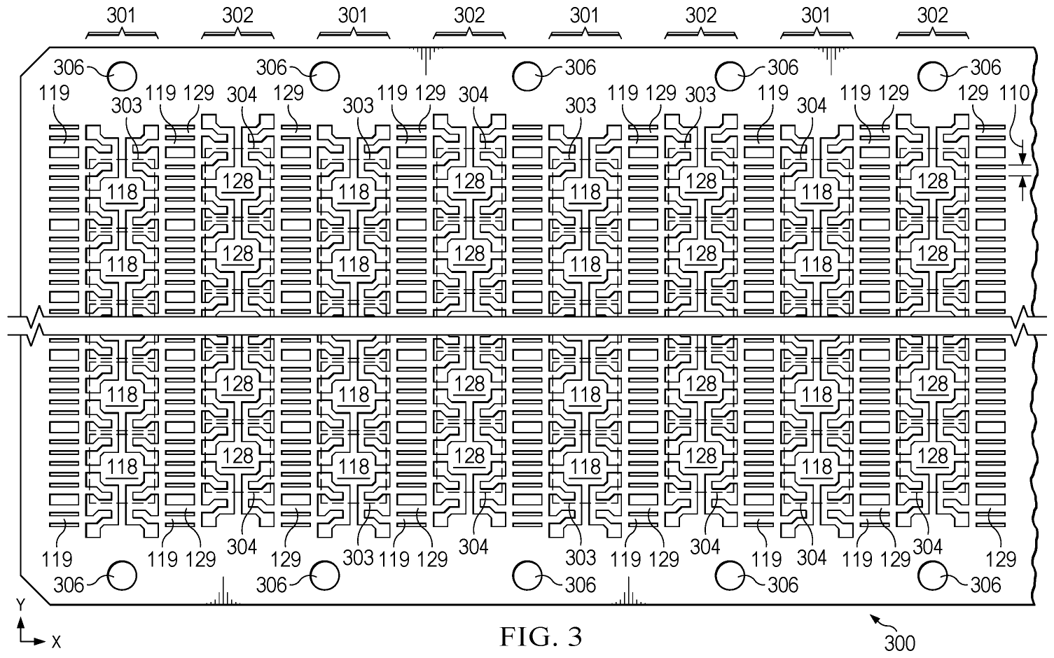

Referring now to FIGS. 2-11, FIG. 2 shows a method 200 for fabricating an electronic device according to another aspect, and FIGS. 3-11 show the example electronic device 100 undergoing fabrication processing according to the method 200 using mold apparatus having insertable blades in a mold. The method 200 includes molded package separation during molding using the insertable blades of the mold apparatus to facilitate the use of interdigitated lead frames with staggered column cavities having multiple unit regions in each column of a lead frame panel array.

The method 200 and the mold apparatus provide a package separation solution that can advantageously reduce integrated circuit manufacturing costs and time. For example, the insertable blade package separation technique does not require column alignment for pitch correction in an interdigitated lead frame, and also avoids the cost and processing time required for subsequent saw cutting operations to separate individual packaged electronic devices concurrently molded in the panel array columns.

Another advantage of the example method 200 and the mold apparatus illustrated and described below is the avoidance of manufacturing cost, time, and complexity associated with zigzag laser cutting for package separation. Instead, the method 200 advantageously provides molded package structure separation for individual packaged electronic devices 100 as part of a molding process. Moreover, some implementations (e.g., described below in connection with FIGS. 12 and 13) provide mold apparatus with selective blade insertion in one or more of the column cavities to allow a single mold apparatus to be used for multiple different lead frame array panel and final packaged electronic device configurations, including devices of different pin counts, etc. This saves the cost of individual molds for each different lead frame array and device types or combinations within a manufacturing facility that fabricates electronic devices using interdigitated lead frame panels.

At 202 in FIG. 2, the method 200 includes providing or creating a starting lead frame strip with interdigitated unit regions in two or more columns. The illustrated examples and the following description discuss first and second columns of an interdigitated lead frame panel and of a corresponding mold apparatus with first and second mold column cavities and respective insertable blades and blade channels. The description with respect to first and second columns is applicable to integrated circuit device manufacturing using lead frame panels and mold apparatus having any number of two or more columns.

FIG. 3 shows a partial top view of an interdigitated lead frame panel 300 (e.g., also referred to as a lead frame strip) made of copper or other suitable conductive metal. The lead frame panel 300 has staggered or offset adjacent columns 301 and 302, each having multiple respective unit regions 303 and 304 for concurrent fabrication of multiple electronic devices. The lead frame panel 300 is illustrated in an example position with alternating staggered rows that extend along a row direction (e.g., the first direction X in the drawings), and the columns 301 and 302 extend along a column direction (e.g., the second direction Y in the illustrated orientation). The lead frame panel 300 includes circular holes 306 located in the peripheral area spaced outwardly above and below the unit regions 303 and 304 to facilitate clamping and controlled positioning of the lead frame panel 300 in a fixture (not shown) during use.

In the illustrated example, the lead frame panel 300 includes a pattern of columns 301 and 302 that are staggered or offset from one another by one pitch spacing distance 110. As described above in connection with FIGS. 1-1C, the pitch spacing distance 110 represents the lead pitch spacing of adjacent leads 119, 129 in the finished packaged electronic devices 100. In other implementations, the adjacent columns are offset by a different distance, such as another integer number of pitch spacing distance is 110. Although the illustrated example includes a repeating pattern of adjacent pairs of alternating and interdigitated first and second columns 301 and 302, other patterns are possible in different implementations. The illustrated lead frame panel 300 as individual columns 301 and 302 having six unit regions in each column for fabrication of the example electronic devices 100 that have three leads on each of the third and fourth sides 103 and 104. Other implementations are possible in which individual columns have different numbers of unit regions and/or unit regions with different lengths along the second direction Y, for example, in lead frame panel arrays used for concurrent manufacturing of two or more different final electronic device types and/or size, such as to facilitate maximization of panel device density or other manufacturing process goals.

The lead frame array 300 in FIG. 3 has conductive metal features in each unit region 303, 304 that define a corresponding die attach pad 118, 128 and shared or joined device leads that are subsequently separated in lead trim operations described below. In this example, the first columns 301 each include six unit regions 303 positioned at respective locations along the column or second direction Y, with prospective leads 119 and respective die attach pads 118. The example second columns 302 each include six unit regions 304 at respective locations along the second direction Y, with respective die attach pads 119 and prospective second leads 129 that are joined to the prospective leads 119 of the unit regions 303 in the adjacent first columns 301, including the offsetting by the pitch spacing distance 110 along the second direction Y.

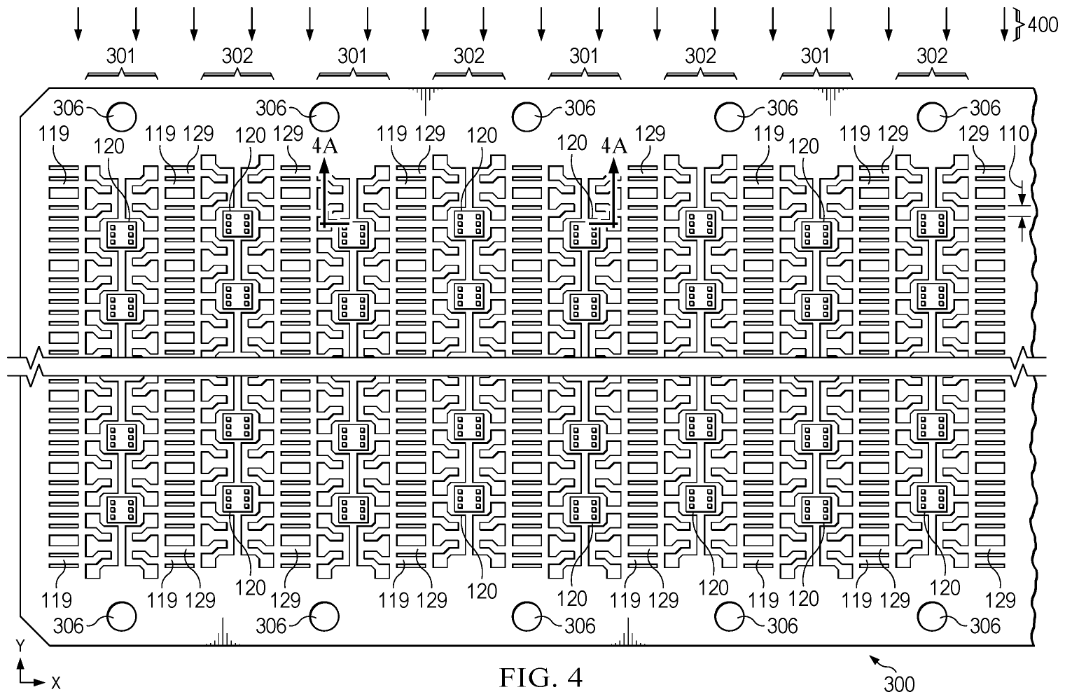

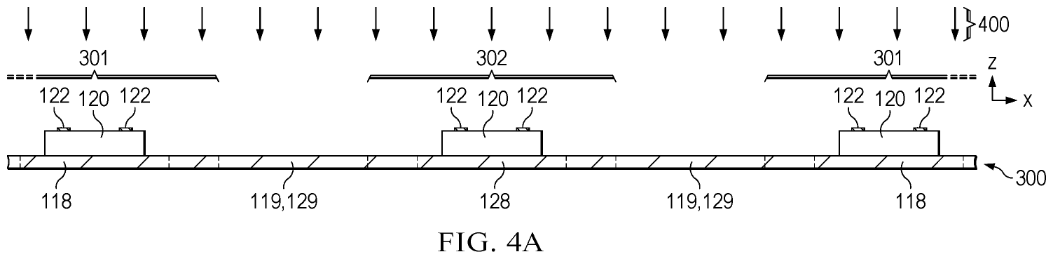

At 204 in FIG. 2, the method 200 includes die attach processing. FIGS. 4 and 4A a show one example, in which a die attach process 400 is performed that attaches semiconductor dies 120 to the die attach pads 118 and 128 of the respective first and second columns 301 and 302. The illustrated example attaches the same type and size of the semiconductor die 120 on each of the die attach pads 118 and 128. In other implementations, different types and/or sizes of semiconductor dies can be attached to respective ones of the die attach pads 118 and 128. In these or other examples, moreover, two or more semiconductor dies or other components (e.g., discrete component such as resistors, capacitors, etc.) can be attached to shared or individual die attach pads in one or more of the unit regions 303 and/or 304 at 204. FIG. 4A shows a partial sectional side elevation view taken along line 4A-4A in the top view of FIG. 4 to show portions of the three example columns during the die attach process 400. In one implementation, the die attach processing includes automated application of an adhesive (not shown) to the respective die attach pads 118 and 128, followed by automated placement of the individual semiconductor dies 120 on the adhesive, for example, using automated pick and place equipment (not shown). In one example, the placement of the semiconductor dies 120 is followed by an optional thermal curing process (not shown) to cure the adhesive and secure the semiconductor dies 120 on the respective die attach pads 118 and 128.

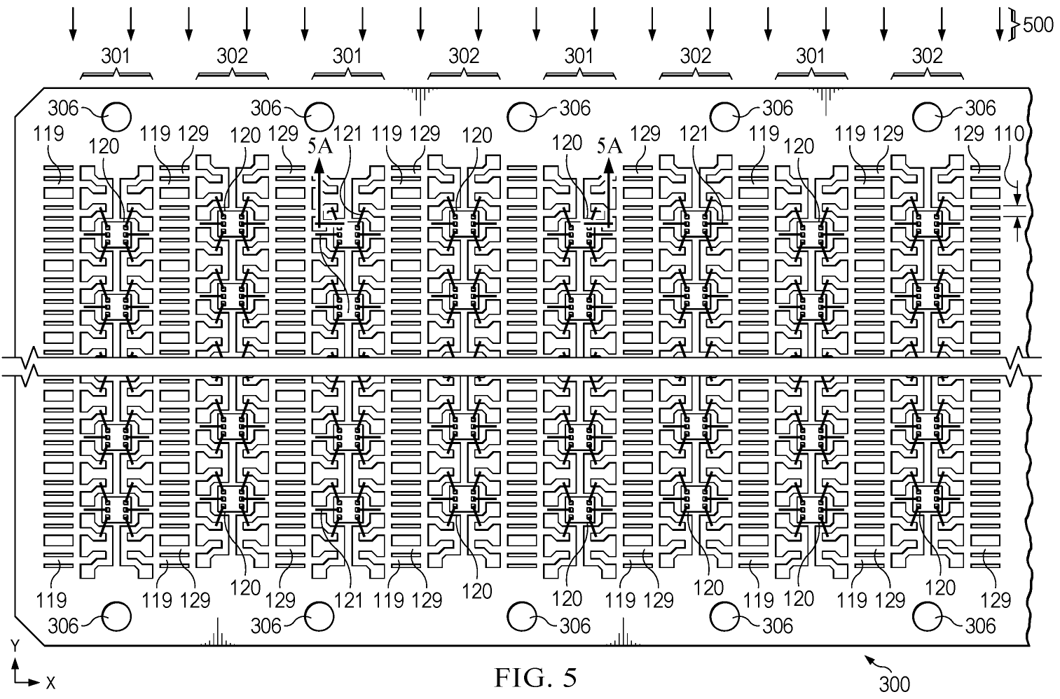

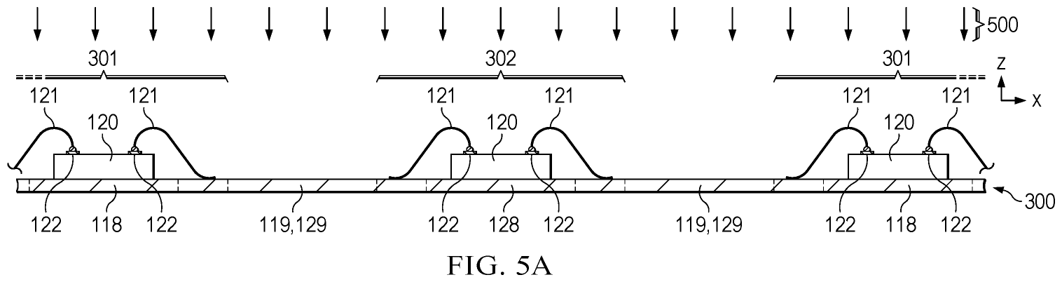

The method 200 also includes electrical connection at 206 in FIG. 2. In the illustrated example, wire bonding is used to form electrical connections between the conductive bond pads 122 of the semiconductor dies 120 and prospective conductive leads 119, 129 in the individual unit regions 303 and 304. In other implementations, the prospective packaged electronic devices include one or more package substrates (not shown), and the die attach processing at 204 and electrical connection processing at 206 are implemented using flip chip die attach processes for direct soldering of conductive terminals of the semiconductor dies to conductive features of the package substrate and/or to conductive features of the lead frame panel 300, alone or in further combination with wire bonding to form additional electrical connections. The respective partial top and sectional side elevation views of FIGS. 5 and 5A show one example, in which a wire bonding process 500 is performed that forms the bond wires 121 that individually connect the respective conductive bond pad 122 of the semiconductor die 120 to a prospective lead 119, 129 in the respective unit regions 303, 304.

At 207 in FIG. 2, the method 200 optionally includes configuring blade insertion locations in mold cavities of a mold apparatus based on the unit regions in the individual lead frame array columns. In one example, the configuration at 207 includes programming actuators of the mold apparatus to enable insertion of one or more mold blades during molding operations, while refraining from inserting one or more other blades, for example, to allow use of a single mold apparatus for fabricating electronic devices using different lead frame panel arrangements.

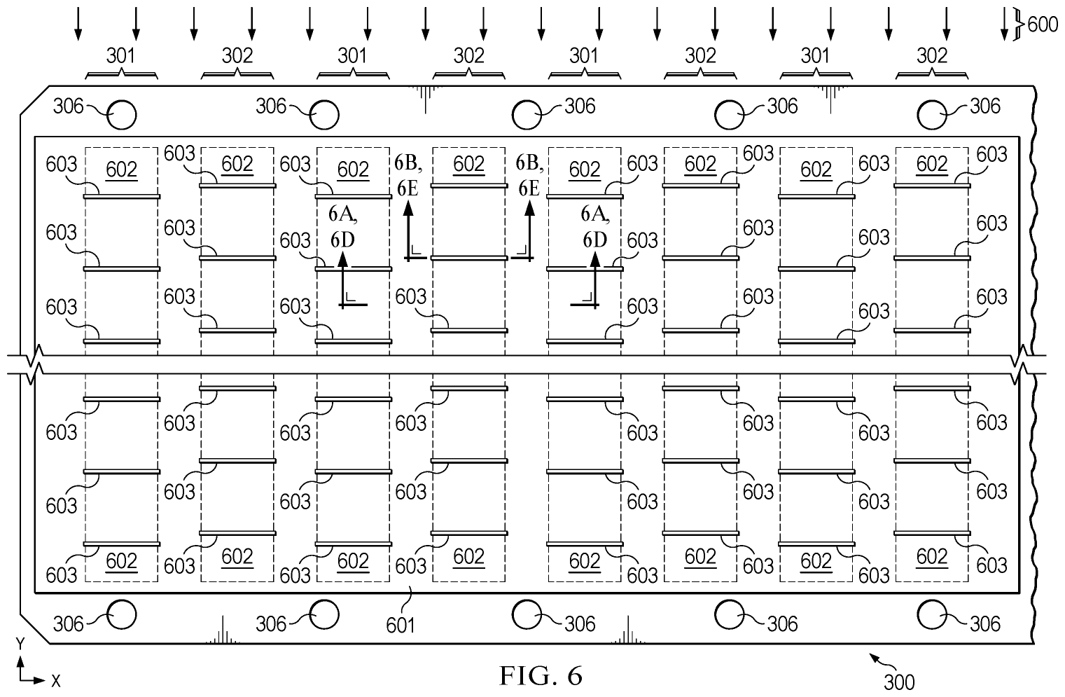

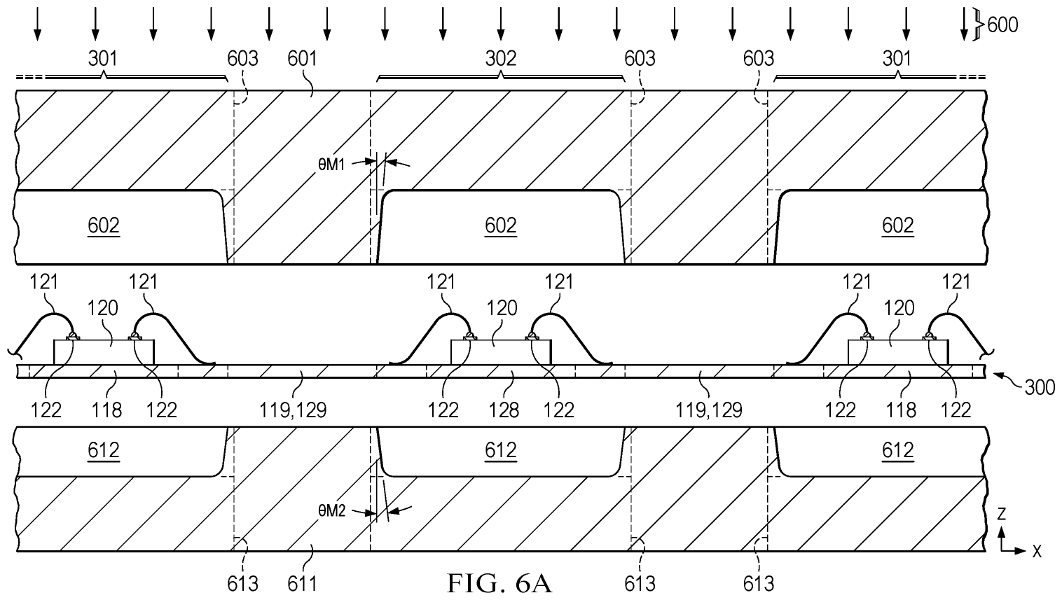

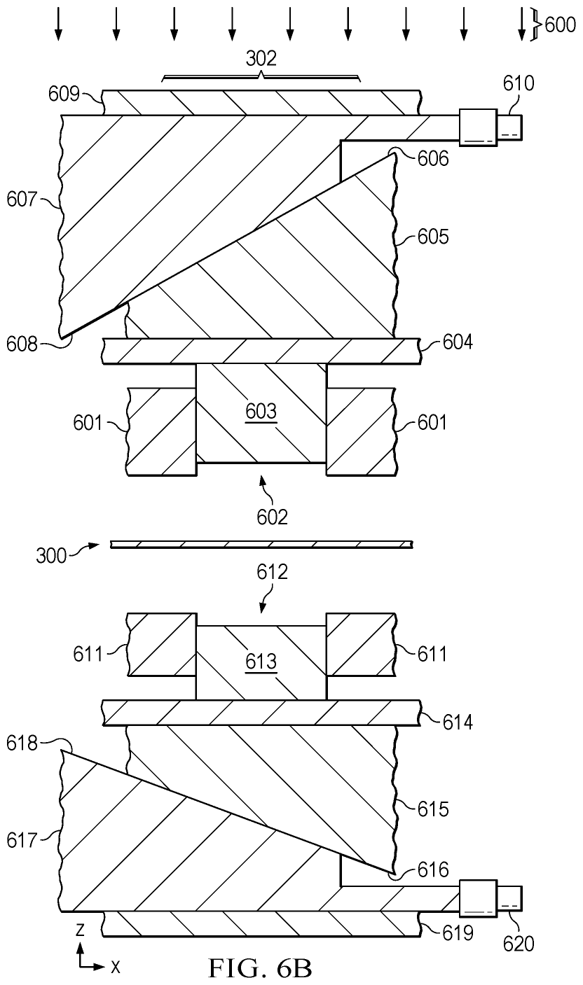

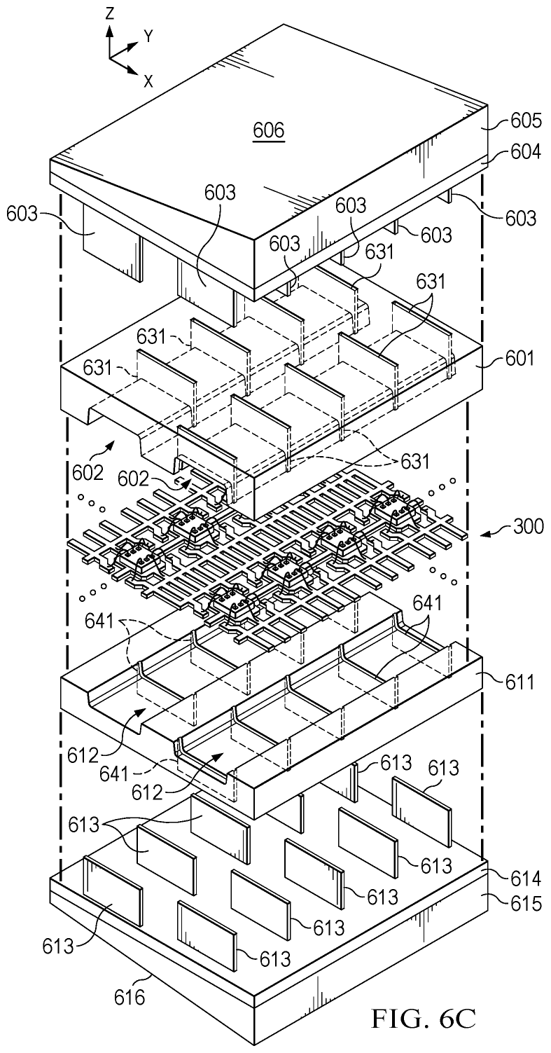

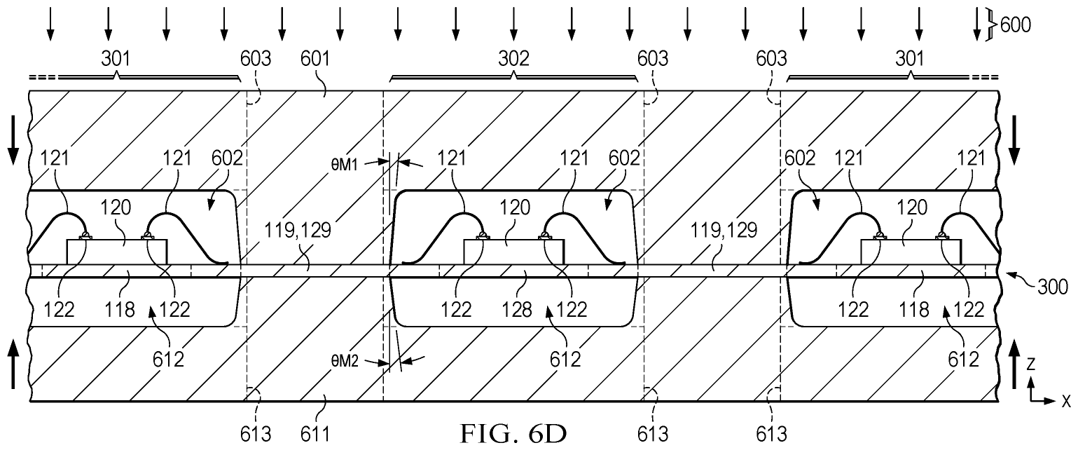

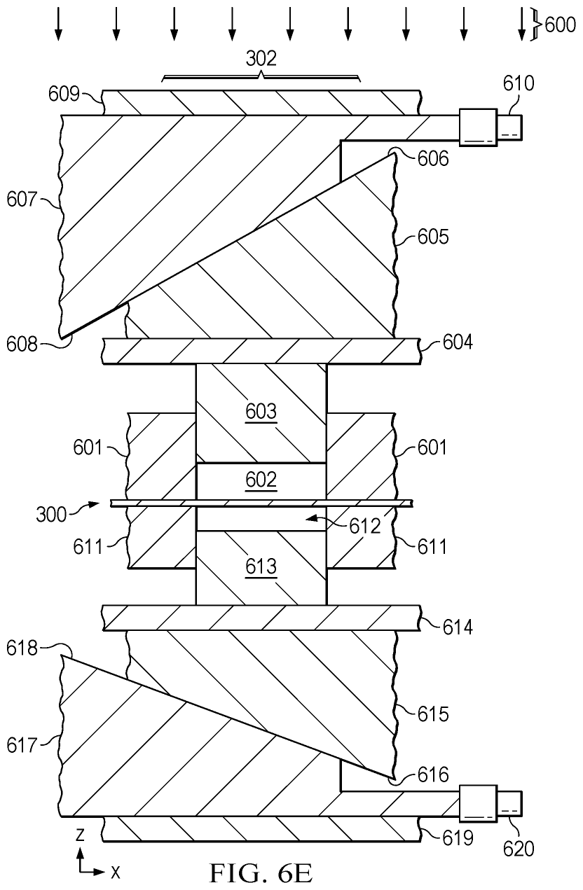

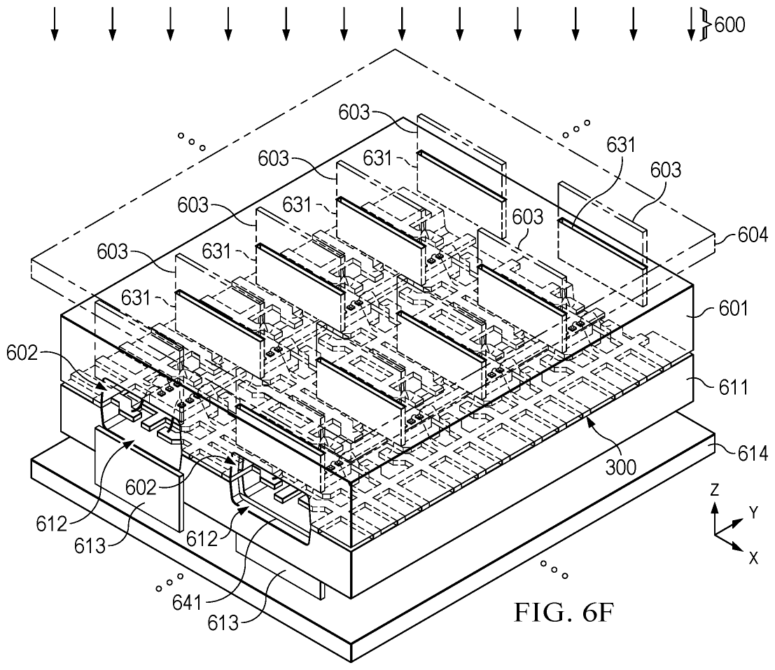

At 208 in FIG. 2, the lead frame panel 300 is installed in a mold with column cavities aligned with columns of unit regions of the lead frame panel, and the upper and lower mold portions are closed for each panel column. FIGS. 6-6D show one example of a panel installation process 600 that installs the lead frame panel 300 into a mold apparatus, and FIGS. 6D-6F illustrate closure of the mold portions to engage the lead frame panel 300. FIG. 6 shows a partial top view, with an upper or first mold portion 601 positioned above the lead frame panel 300 with upper or first mold column cavities 602 aligned with the respective columns 301 and 302 of the lead frame panel 300.

As further shown in FIG. 6A, the first mold portion 601 includes upper or first blades 603 in a retracted position in blade channels of the first mold portion 601. The upper mold cavities 602 have sidewalls used in forming the first or upper portions of the respective third and fourth sides 103 and 104 of the finished packaged electronic devices 100 (e.g., FIG. 1 above), and the sidewalls of the upper mold cavities 602 extend at the first angle θM1 to the third direction Z as shown in FIG. 6A. The mold apparatus also includes a second or lower portion 611 positioned below the lead frame panel 300. The lower portion 611 has lower or second column cavities 612 and second or lower blades 613 in a retracted position in corresponding lower or second blade channels of the lower mold portion 611. The lower mold cavities 612 have sidewalls used in forming the lower portions of the respective third and fourth sides 103 and 104 of the finished packaged electronic devices 100 and the sidewalls of the lower mold cavity 612 extend at the second mold angle θM2 to the third direction Z as shown in FIG. 6A. The blade cavities and the associated blades 603 and 613 in one example are elongated structures that extend along the first direction X.

The illustrated mold apparatus includes first and second (e.g., upper and lower) mold portions to facilitate fabrication of the molded package structure 108 (e.g., FIG. 1) to accommodate dual in-line package or other device package types having the leads 119, 129 extending outward from the respective third and fourth sides 103 and 104. In this example, the upper and lower mold portions 601 and 611 each have respective column cavities 602 and 612. In other examples, for example quad flat or other no-lead devices, only one of the mold portions includes corresponding column cavities, such as an upper mold portion with upper column cavities, and a lower mold portion with a flat surface to form the bottom of the molded package structure.

FIG. 6B shows a partial sectional side elevation view taken along line 6B-6B of FIG. 6 to illustrate further details of a portion of the mold apparatus for one column 302 with the movable blades 603 and 613 in the retracted positions prior to mold closure, and FIG. 6C shows a partial exploded view with details of the mold apparatus of FIGS. 6-6B.

As seen in FIGS. 6B and 6C, the upper features of the example mold apparatus include the upper portion 601 with the upper column cavities 602, as well as upper blade cavities 631 (FIG. 6C) in which all or portions of the upper blades 603 are located in the illustrated retracted position. The upper blades 603 in this example are mounted on, or form a part of, an upper blade panel 604, and the upper apparatus includes an upper blade ramp 605 with a tapered top side 606. As further seen in FIG. 6B, an upper actuator mechanism in this example includes an actuator ramp 607 with a tapered bottom side 608 that engages the top side 606 of the upper blade ramp 605, and the top side of the upper actuator ramp 607 is sliding engaged with an upper support structure 609. An upper servomotor actuator 610 is structurally engaged with the upper actuator ramp 607 as shown in FIG. 6B, and a mold apparatus controller (not shown) is programmed to operate the servomotor actuator 610 to selectively translate the upper actuator ramp 607 along the first direction X (e.g., to the right in FIG. 6B) for blade insertion by interaction of the tapered sides 606 and 608 to move the upper blade panel 604 and the blades 603 downward (e.g., along the negative third direction, −Z) for device package separation as explained further below. In one example, the upper portion of the mold apparatus includes biasing structures, such as springs (not shown) to bias the blade 603 and the upper blade panel 604 upward to translate the upper blades 603 up during a blade retraction step.

The lower mold apparatus features include the lower portion 611 with the lower column cavities 612, as well as lower blade cavities 641 (FIG. 6C) in which all or portions of the lower blades 613 are located in the retracted position. The lower blades 613 are mounted on, or form a part of, a lower blade panel 614, and the lower apparatus includes a lower blade ramp 615 with a tapered lower side 616. A lower actuator mechanism includes an actuator ramp 617 with a tapered upper side 618 that engages the lower side 616 of the lower blade ramp 615, and the bottom side of the lower actuator ramp 617 is sliding engaged with a lower support structure 619. A lower servomotor actuator 620 is structurally engaged with the lower actuator ramp 617 as shown in FIG. 6B, and the mold apparatus controller operates the servomotor actuator 620 to selectively translate the lower actuator ramp 617 to the right in along the first direction X for blade insertion by interaction of the tapered sides 616 and 618 to move the lower blade panel 614 and the blades 613 upward along the third direction Z for device package separation. The lower portion of the mold apparatus in this example also includes biasing structures, such as springs (not shown) to bias the blades 613 and the lower blade panel 614 downward to translate the lower blade 613 down while the servomotor actuator 620 translates the lower actuator ramp 617 back to the right during blade retraction after device package separation.

FIGS. 6D-6F show closure of the mold portions 601 and 611 to engage the lead frame panel 300. During mold closure in this example, the upper and lower blades 603 and 613 remain in the retracted positions at least partially within the respective blade cavities 631 and 641 (FIG. 6F). As shown in FIGS. 6D and 6E, the closure of the mold part of a lower side of the upper mold portion 601 with a top side of the lead frame panel 300 and engages part of an upper side of the lower mold portion 611 with the bottom side of the lead frame panel 300. Closure of the mold portion 601 and 611 creates unified column mold cavities that include the respective upper and lower portion 602 and 612 for each of the lead frame panel array columns prior to molding compound injection. The unified column mold cavities, moreover, are in fluidic communication with the respective upper and lower blade cavity 631 and 641. The mold apparatus includes inlet and outlet ports (not shown) for each unified blade cavity to facilitate subsequent injection of molding compound, for example, using suitable injection molding systems, and the lead frame panel 300 can include dam bars, tie bars, and/or other structures (not shown) to form an otherwise sealed cavity for each column during molding operations in the closed position of FIGS. 6D-6F.

As shown in FIG. 6F, the upper and lower mold portions 601 and 611 each have five respective blade cavities 631 and 641 for subsequent separation of six molded package structures during molding operation for each respective unified column cavity and associated column 301, 302 of the lead frame panel 300. In other implementations, the upper and lower mold portions 601 and 611 may each have only a single blade cavity to facilitate insertion of a single blade or may have a different integer number of blade cavities and associated blades for separating three or more molded package structures within the respective column cavities.

In one implementation, the mold apparatus is configurable by selective inclusion or absence of blades in one or more of the respective blade cavity 631 and 641 to accommodate a particular interdigitated lead frame panel design, for example, based on the column direction length of the unit regions 303 and 304, and the positions of the upper and lower blade cavities 631 and 641 are such that blade-based package structure separation can be accommodated during molding operations for any desired package structure boundary in all unit region variations and corresponding lead frame panel designs for which the mold apparatus will be used. This implementation allows the use of a single actuation mechanism (e.g., including the upper and lower servomotor actuator 610 and 620) with the configuration of the mold apparatus (e.g., at 207 in FIG. 2) being implemented by upper and lower blade structures (e.g., blade panels 604 and 614) with one or more corresponding blade 603, 613 in the appropriate locations.

In another implementation, separate actuator mechanisms and individual blade actuation structures are provided for each of a number of locations (e.g., rows) along the second direction Y to allow programmable or configurable selective insertion of all or fewer than all the blades for a given lead frame panel design. This approach may involve more complex actuation structures but facilitates faster programmatic reconfiguration of the mold apparatus during changeover for mold processing of different lead frame panel designs.

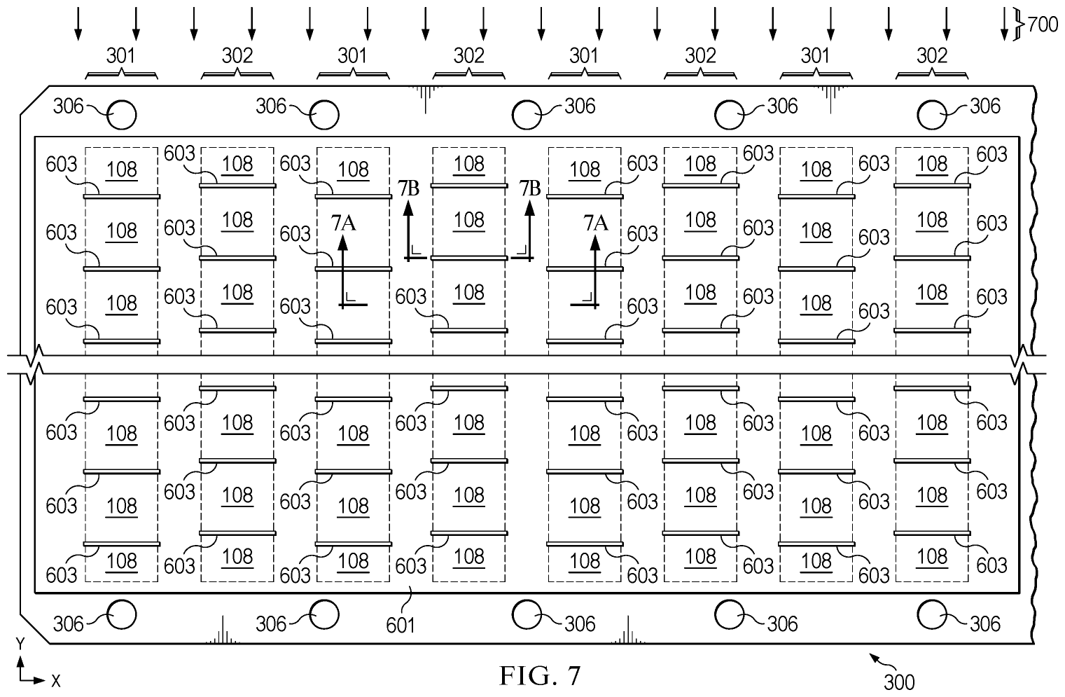

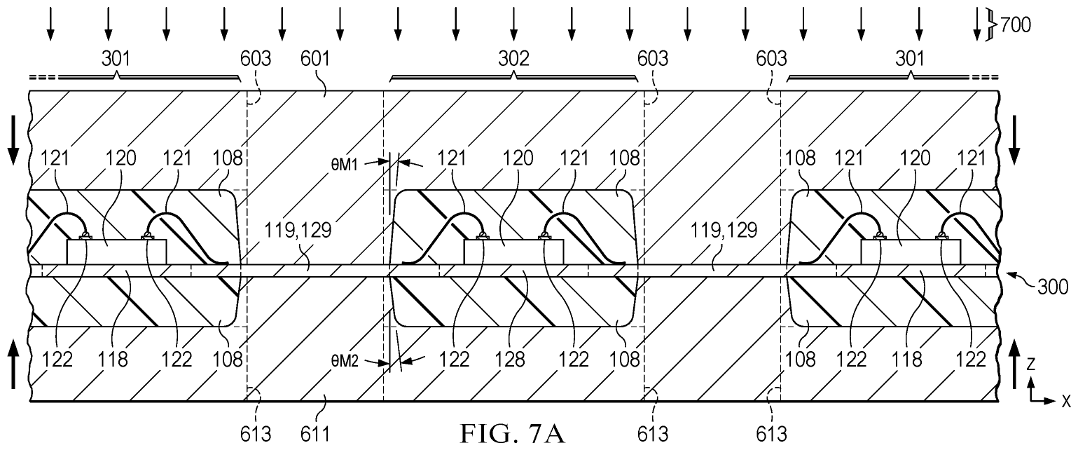

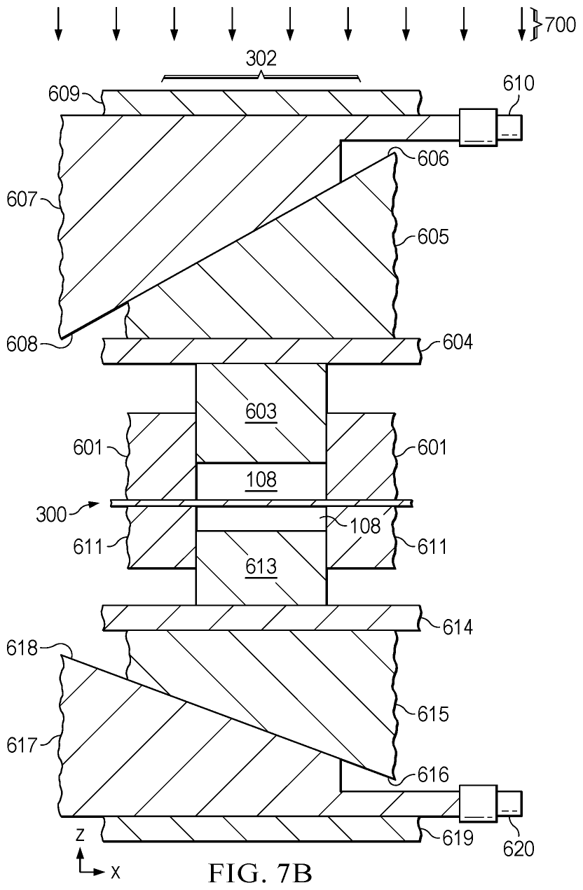

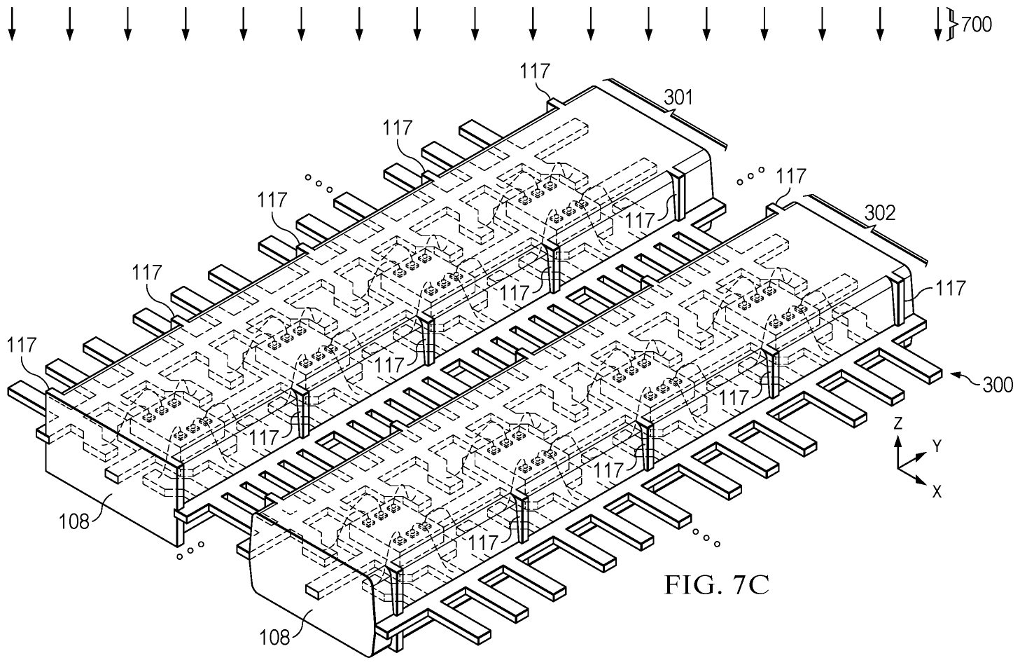

The method 200 continues at 210 in FIG. 2 with molding compound injection into the unified mold column cavities. FIGS. 7-7C illustrate one example, in which a molding compound injection process 700 is performed that injects molding compound 108 into the upper and lower mold column cavities 602 and 612 through one or more suitable injection ports, for example, while exhaust or outlet ports (not shown) are opened to allow flow of molten molding compound. In one implementation, the blade actuator structures are not enabled until the mold column cavities 602 and 612 are filled, and the blades 603 and 613 remain in the retracted positions during mold filling. In another example, the blades 603 and 613 can be inserted, or partially inserted, prior to complete filling of the mold cavities 602 and 612. In the example of FIGS. 7-7C, the movable blades 603 and 613 remain in the retracted position during the molding compound injection process 700, and the process 700 at least substantially fills the cavities to form structures 108 that extend along the entire length of each column cavity. FIG. 7C illustrates two adjacent column cavities filled with the molding compound 118 prior to blade insertion into the column cavities of the mold apparatus.

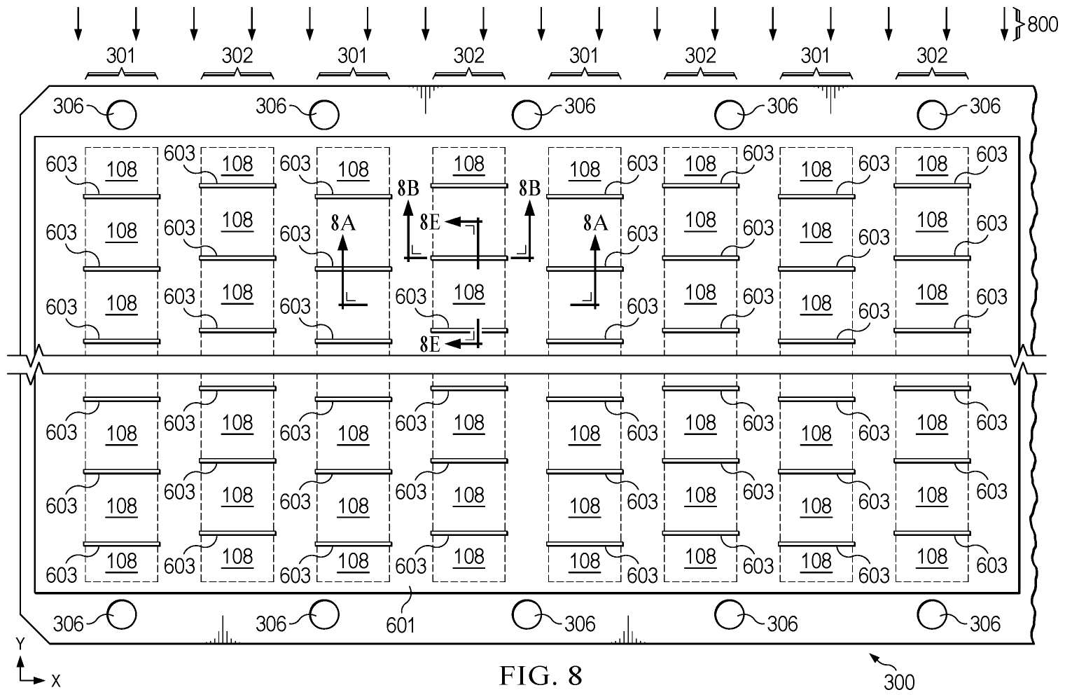

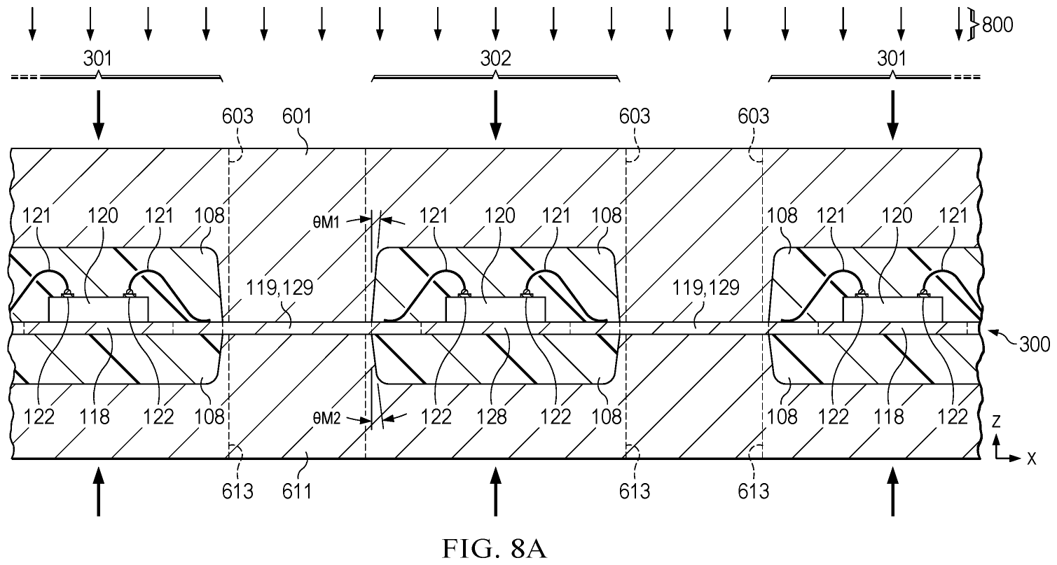

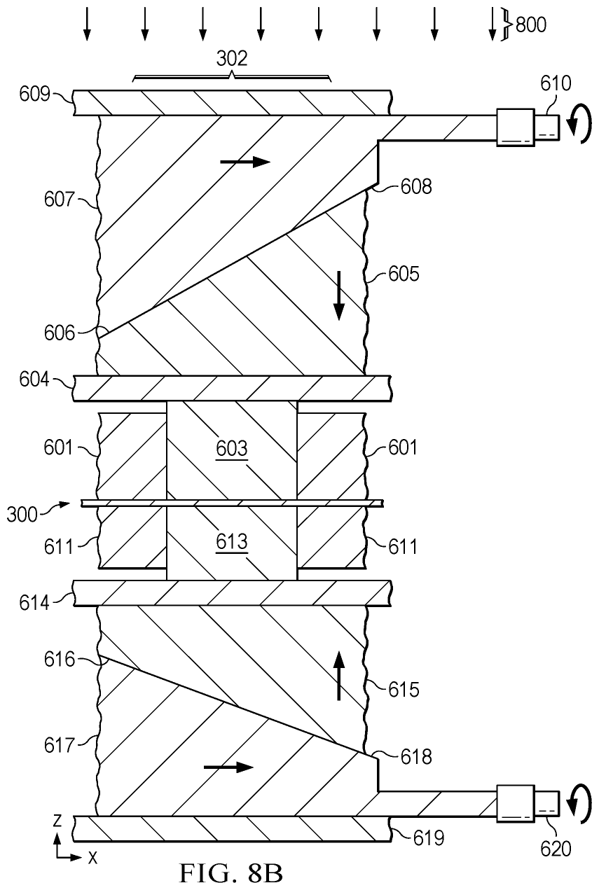

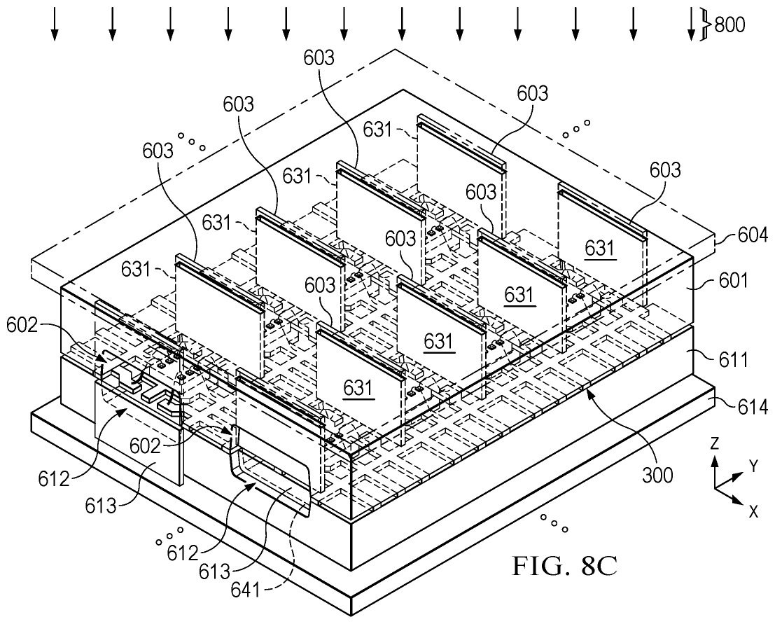

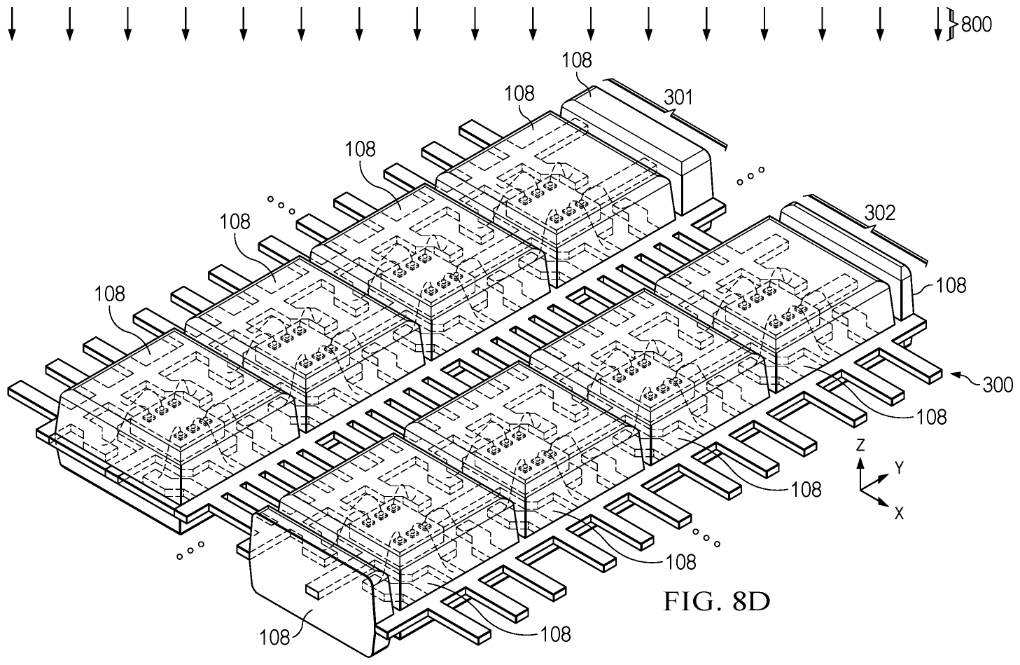

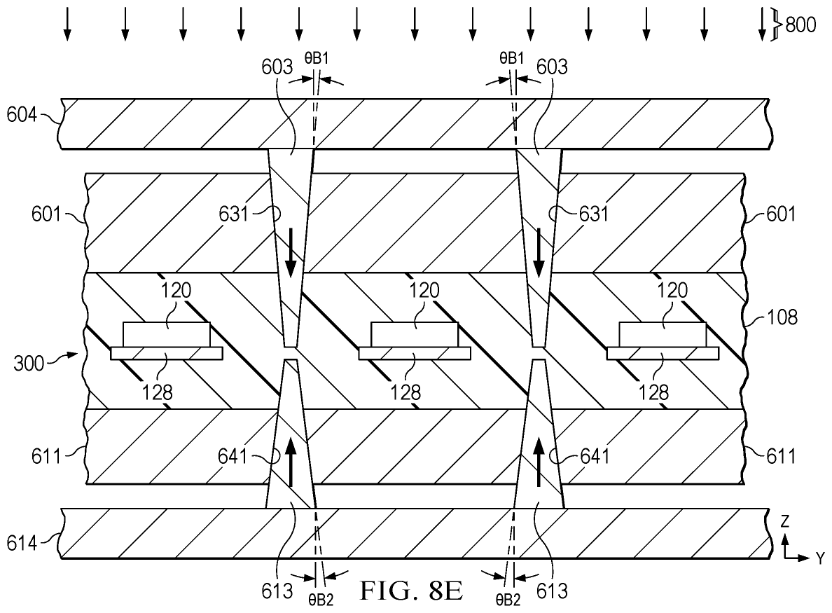

At 212 in FIG. 2, the method 200 continues with blade insertion. FIGS. 8-8D illustrate one example, in which a blade insertion process 800 is performed that inserts one or more blades 603 and 613 from the respective blade cavities 631 and 641 into the column cavities of the mold between the adjacent unit regions 303 and 304 of the lead frame panel 300. The blade insertion process 800 separates individual molded package structures 108 in the respective column cavities 602, 612 of the mold along a column direction Y. As shown in FIG. 8A, the upper blades 603 are inserted downward from the respective blade channels 631 into the respective column cavities 602 in the direction toward the lead frame panel 300, and the upper blade 603 ultimately engage with portions of the top side of the lead frame panel 300. In addition, the lower blades 613 are concurrently translated upward from the respective lower blade channel 641 into the lower column cavities 612 to engage with portions of the bottom side of the lead frame panel 300. FIG. 8B illustrates the translation of the actuator ramps 607 and 617 to the right by operation of the respective servomotor actuator 610 and 620, which causes the downward insertion of the upper blade 603 and the upward insertion of the lower blade 613 in the illustrated lead frame column 302.

FIG. 8C illustrates two columns of the mold apparatus in the closed position with the blades 603 and 613 inserted into the respective column cavities 602 and 612. FIG. 8D shows two adjacent column cavities with multiple individual molded package structures in the respective column cavities along the column direction after blade separation. FIG. 8E is a partial sectional side elevation view taken along line 8E-8E of FIG. 8 showing the respective upper and lower blades 603 and 613 in the inserted position to separate molded package structures 108 in the column cavity along the second direction Y. As seen in FIG. 8E, the upper blades 603 have opposite sidewalls spaced apart from one another along the second direction Y and the upper blade sidewalls extend at the first blade angle θB1 to the third direction Z. In addition, the lower blade 613 have tapered opposite sidewalls spaced apart from one another along the second direction Y at the second blade angle θB2 to the third direction Z. In one example, the upper and lower blade cavities 631 and 641 have sidewalls at or near the respective first and second blade angles θB1 and θB2. As seen in FIGS. 6C and 8C, moreover, the upper blade cavities 631 and the lower blade cavity 641 in adjacent columns are offset from one another along the second direction Y such that the respective blades 603 and 613 are inserted at different locations along the second direction Y for adjacent respective column cavities 602 and 612 of the mold.

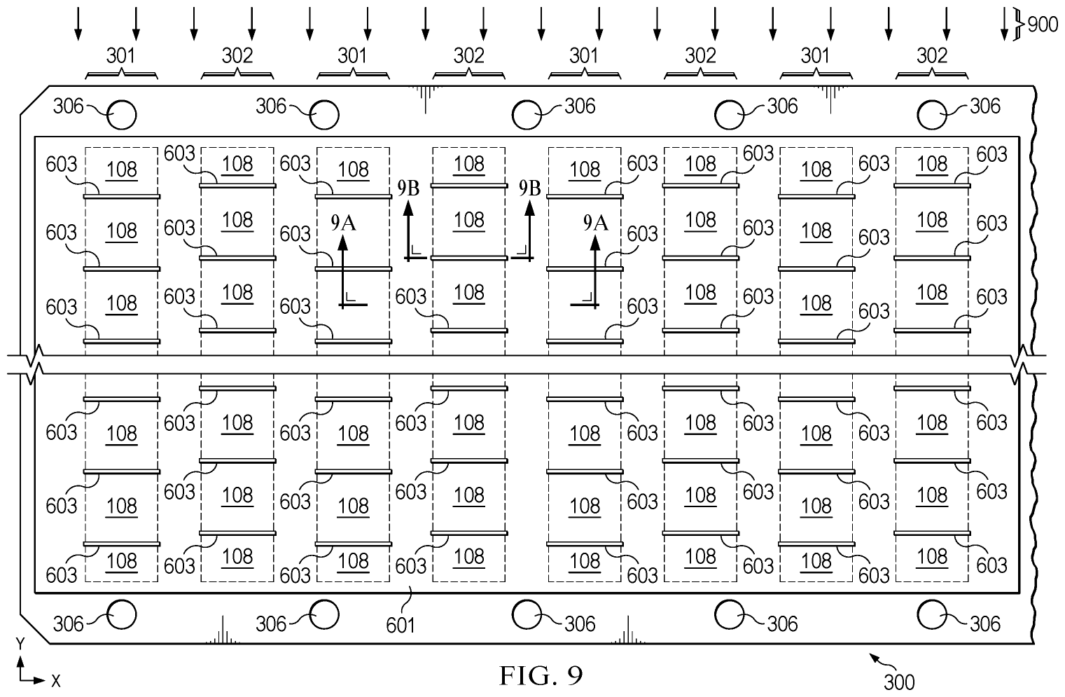

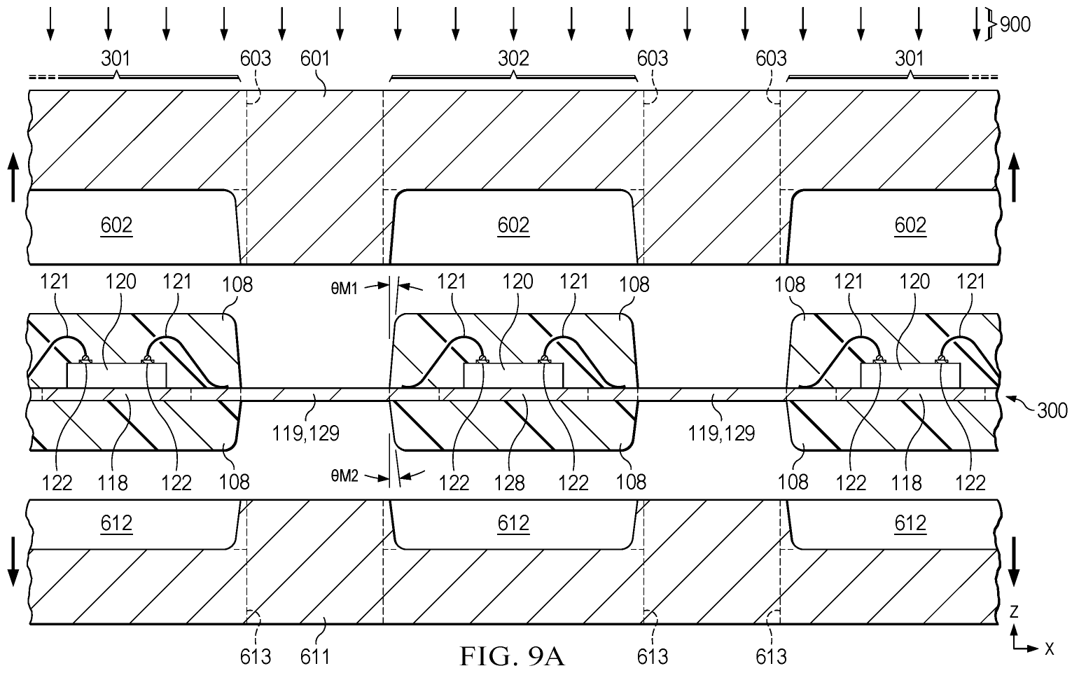

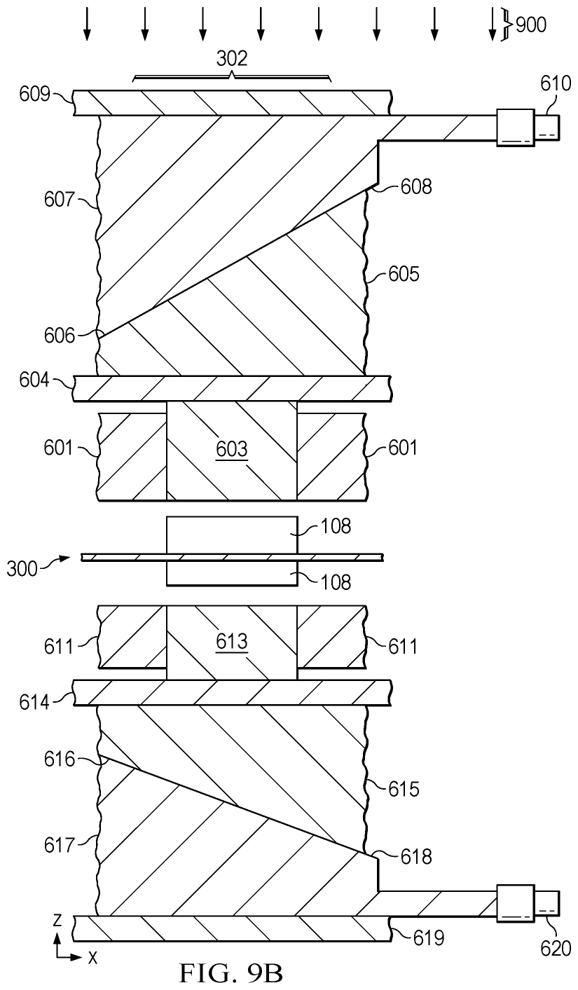

At 214 in FIG. 2, the method 200 includes opening the mold by separating the mold portions along the third direction Z and moving the blades 603 and 613 along the third direction Z away from the lead frame panel 300. FIGS. 9-9B illustrate one example, in which a mold opening process 900 is performed that concurrently opens the mold by separating the mold portion 601 and 611 in opposite directions and concurrently withdraws the blade 603 and 613 into the respective blade cavities 631 and 641 along the third direction Z. In another example, the blades 603 and 613 are withdrawn into the retracted positions prior to separating the mold portion 601 and 611. In a further example, the mold is opened by separating the mold portion 601 and 611 along the third direction Z prior to withdrawing the blade 603 and 613 into the retracted positions.

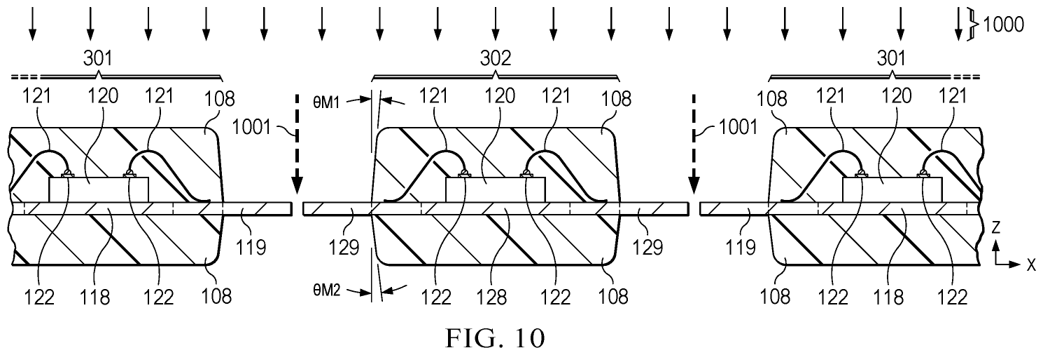

At 216 in FIG. 2, the method 200 in one example further includes lead trimming along the column direction Y to separate leads of adjacent columns. FIG. 10 shows a partial sectional side view example, in which a lead trimming process 1000 is performed that separates the previously joined leads 119 and 129 from one another, for example, by punch die equipment, saw cutting equipment, laser cutting equipment, or the like along cutting directions 1001. The lead separation or trimming process 1000 can also include separating tie bars, adjacent leads 119, 129, and other structural features of the starting lead frame panel 300 (not shown).

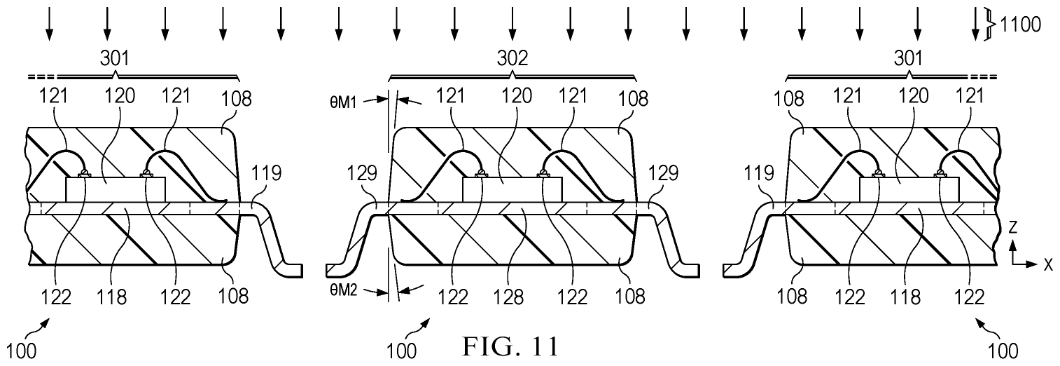

218 in FIG. 2, the method 200 continues with optional lead forming. FIG. 11 shows one example, in which a lead forming process 1100 is performed that bends the leads 119 and 129 into the example gullwing shape. In other implementations, the lead forming process 1100 forms the leads 119 and 129 into different shapes (e.g., “J” leads). In other examples (e.g., no-lead package types), no lead forming operations are undertaken and the processing at 218 in FIG. 2 is omitted.

Referring also to FIGS. 12, 12A, 13 and 13A, in another aspect, the mold apparatus is configurable with respect to the number and locations of the movable blades 603, 613. FIG. 12 shows a partial view of a further example configuration of a portion of the mold apparatus with configurable blade insertion locations and corresponding blade cavities 631 and 641, some of which do not include respective blades 603 and 613. FIG. 12 shows the mold apparatus in the closed position after mold compound injection and prior to blade insertion, for example, during the mold compound injections 700 described above. The selective use of blade 603 and 613 in fewer than all of the available blade insertion locations of the blade cavities 631, 641 facilitates the use of a single mold with multiple pin count packaged electronic device designs. FIG. 12A illustrates two example columns of the lead frame panel molding compound injection prior to blade insertion. As seen in FIG. 12A, the filled cavities include the protrusions 117 corresponding to the shapes in the injected molding compound 108 prior to insertion of any of the blade 603 and 613.

FIG. 13 illustrates the same portion of the configurable or programmable blade insertion mold apparatus in the closed position with the movable blades in the inserted position, for example, during or following the blade insertion process 800 described above. FIG. 13A shows the two example columns of the lead frame panel and mold apparatus with multiple separated individual molded package structures 108 in each column cavity. In this example, three upper blades 603 and three lower blades 613 are inserted into each column cavity of the mold during the blade insertion process 800, and these blade insertions result in separations between adjacent individual package structures 108. In addition, the lack of inserted blades 603 or 613 in select ones of the respective upper and lower blade cavities 631 and 641 leaves the previously molded protrusions 117 between the ends of the individual molded package structures 108. The provision of one or more blade cavities 631 and 641 which are not used for blade insertion in a given lead frame panel 300 can result in molded protrusions 117 remaining as artifacts in the center of the separated molded package structures 108 as shown in FIG. 13A, or at one or more different locations along the second (e.g., column) direction Y, for example, as shown in the electronic device examples 100 of FIGS. 1B and 1C above. However, as previously discussed, the programmable or configurable implementations advantageously facilitate the use of common mold apparatus or portions thereof to facilitate electronic device fabrication for two or more lead frame panel designs 300, thereby facilitating cost savings and manufacturing complexity reduction in the production of packaged electronic devices.

FIG. 14 shows the example electronic device 100 having the indents 115 and 116 as described above in connection with FIG. 1A along with example ribbed upper blades 1403. As the blades (e.g., the blades 303 and 313 described above) are inserted into the corresponding column cavities during molding (e.g., after mold insertion and prior to molding compound curing), and since the corresponding column cavities (e.g., 302, 312) are substantially closed spaces, the package separation blades may be subjected to significant pressures during insertion. To accommodate the pressure within the mold cavities as well as the force required to separate individual molded package structures during molding operations, the blades 1403 in the example of FIG. 14 include rib features 1410 on both opposite sides that are spaced apart from one another along the second direction Y. In this example, the corresponding blade cavities (not shown in FIG. 14) include similar conforming sidewalls having channels to accommodate the ribs 1410, and the lower blades and blade cavities (not shown) are similarly constructed with ribs on both opposite tapered sides of each blade, with the taper corresponding to the above-described blade angle θB1. The illustrated example creates the indents 115 and 116 along the fifth and sixth sides 105 and 106 as shown in FIG. 1A above. In another implementation, each blade 1403 has only one, rib 1410, and the resulting molded package structure 108 can have only a single indent on the fifth side 105 or the sixth side 106, but not on both.

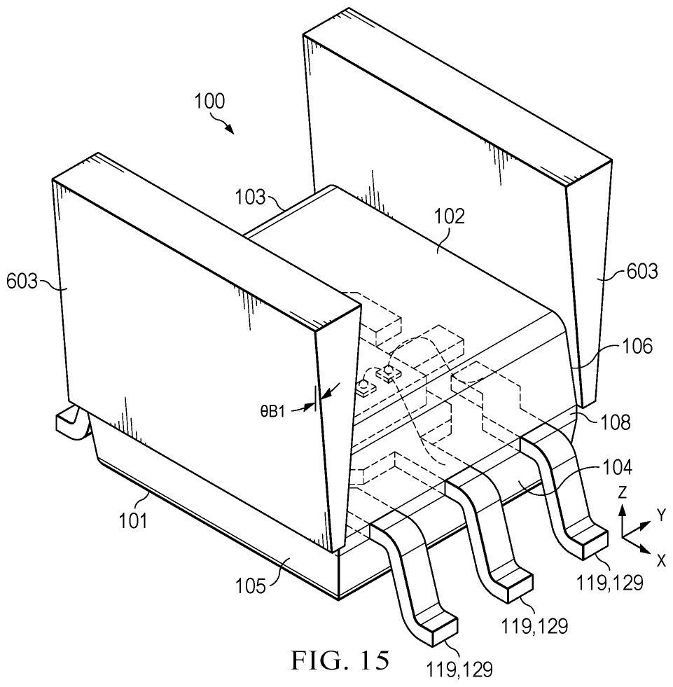

FIG. 15 shows another example using the above-described tapered blades 103 having tapered opposite sides at the first blade angle θB1 to the third direction Z. As previously discussed, this blade insertion separates adjacent molded packages 108 from one another along the column or second direction Y and forms the upper portion of the fifth and sixth sides 105 and 106 at the first blade angle θB1 to the third direction Z without forming the indents 115 or 116 described above in connection with FIGS. 1A, 1B, and 14. The selective programmable aspects described above can result in molded package structures 108 having no indents 115, 116 and no protrusions 117 (e.g., FIG. 1 above), package structures 108 having one or more indents 115, 116 and no protrusions (e.g., FIGS. 1A and 14), package structures having one or more indents 115, 116 and protrusions 117 (e.g., FIG. 1B), and package structures 108 having protrusions 117 and no indents 115 or 116 (e.g., FIG. 1C).

Modifications are possible in the described examples, and other implementations are possible, within the scope of the claims.

What is claimed is:

1. A method, comprising:
injecting molding compound into respective column cavities of a mold to enclose semiconductor dies of respective unit regions of a lead frame panel in the respective column cavities; and
inserting a blade into the respective column cavities of the mold between adjacent unit regions of the lead frame panel to separate individual molded package structures in the respective column cavities of the mold along a column direction.

2. The method of claim 1, further comprising inserting a second blade into the respective column cavities of the mold to separate three or more molded package structures in the respective column cavities of the mold.

3. The method of claim 2, wherein inserting the blade into the respective column cavities of the mold comprises:
inserting first and second upper blades into respective upper column cavities of an upper portion of the mold between the adjacent unit regions; and
inserting first and second lower blades into respective lower column cavities of a lower portion of the mold between the adjacent unit regions.

4. The method of claim 3, comprising filling the respective upper and lower column cavities with the molding compound before inserting the first and second upper blades into the respective upper column cavities and before inserting the first and second lower blades into the respective lower column cavities.

5. The method of claim 2, comprising filling the respective column cavities with the molding compound before inserting the blade and the second blade into the respective column cavities.

6. The method of claim 1, wherein inserting the blade into the respective column cavities of the mold comprises:
inserting an upper blade into respective upper column cavities of an upper portion of the mold between the adjacent unit regions; and
inserting a lower blade into respective lower column cavities of a lower portion of the mold between the adjacent unit regions.

7. The method of claim 6, comprising filling the respective upper and lower cavities with the molding compound before inserting the upper blade into the respective upper column cavities and before inserting the lower blade into the respective lower column cavities.

8. The method of claim 1, comprising filling the respective column cavities with the molding compound before inserting the blade into the respective column cavities.

9. The method of claim 1, comprising inserting the blade at different locations along the column direction for adjacent respective column cavities of the mold.

10. The method of claim 1, further comprising:
configuring blade insertion locations for the respective column cavities of the mold based on the respective unit regions of the lead frame panel.

11. An apparatus, comprising:
a mold having column cavities and blade channels, the column cavities spaced apart from one another along a first direction and the column cavities extending along a second direction that is orthogonal to the first direction, and the blade channels extending into a respective column cavity along a third direction that is orthogonal to the first and second directions;
blades positioned in respective blade channels of the mold; and
an actuator configured to insert portions of the blades from the respective blade channels into the respective column cavities toward a lead frame panel along the third direction to separate individual molded package structures between adjacent unit regions of the lead frame panel in the respective column cavities along the second direction.

12. The apparatus of claim 11, wherein:
the mold comprises first and second blade channels extending into each respective column cavity along the third direction;
the apparatus comprises first and second blades positioned in the respective first and second blade channels for each respective column cavity; and
the actuator is configured to insert portions of the first and second blades from the respective first and second blade channels into each respective column cavity toward the lead frame panel along the third direction to separate three or more individual molded package structures between adjacent unit regions of the lead frame panel in each respective column cavity along the second direction.

13. The apparatus of claim 12, wherein:
the mold comprises an upper portion, a lower portion, upper column cavities, and lower column cavities, the upper portion having first and second upper blade channels extending into each respective upper column cavity along the third direction, and the lower portion having first and second lower blade channels extending into each respective lower column cavity along the third direction;
the apparatus comprises first and second upper blades positioned in the respective first and second upper blade channels of each respective upper column cavity;
the apparatus comprises first and second lower blades positioned in the respective first and second lower blade channels of each respective lower column cavity; and
the actuator is configured to: insert portions of the first and second upper blades from the respective first and second upper blade channels into each respective upper column cavity toward the lead frame panel along the third direction; and to insert portions of the first and second lower blades from the respective first and second lower blade channels into each respective lower column cavity toward the lead frame panel along the third direction, to separate three or more individual molded package structures between adjacent unit regions of the lead frame panel in each respective column cavity along the second direction.

14. The apparatus of claim 11, wherein:
the mold comprises an upper portion, a lower portion, upper column cavities, and lower column cavities, the upper portion having an upper blade channel extending into each respective upper column cavity along the third direction, and the lower portion having a lower blade channel extending into each respective lower column cavity along the third direction;
the apparatus comprises an upper blade positioned in the upper blade channel of each respective upper column cavity;
the apparatus comprises a lower blade positioned in the lower blade channel of each respective lower column cavity; and
the actuator is configured to: insert portions of the upper blade from the respective upper blade channel into each respective upper column cavity toward the lead frame panel along the third direction; and to insert portions of the lower blade from the respective blade channel into each respective lower column cavity toward the lead frame panel along the third direction, to separate the individual molded package structures between adjacent unit regions of the lead frame panel in each respective column cavity along the second direction.

15. The apparatus of claim 11, wherein the actuator is configured to insert the portions of the blades from the respective blade channels into the respective column cavities after the respective column cavities are filled with molding compound.

16. The apparatus of claim 11, wherein:
adjacent column cavities are offset from one another along the second direction; and
the blade channels of adjacent column cavities are offset from one another along the second direction.

17. The apparatus of claim 11, wherein the actuator is configured to selectively insert portions of fewer than all the blades of the respective blade channels.

18. The apparatus of claim 11, wherein the respective blades each include a rib extending outward from each of two opposite tapered sides of the respective blades along the second direction.

19. An electronic device, comprising:
a molded package structure having: a first side; a second side; a third side; a fourth side; a fifth side; and a sixth side, the third and fourth sides spaced apart from one another along a first direction, the fifth and sixth sides spaced apart from one another along a second direction that is perpendicular to the first direction, and the first and second sides spaced apart from one another along a third direction that is perpendicular to the first and second directions;
conductive leads extending out of the third and fourth sides of the molded package structure; and
one of a protrusion extending along the first direction out of one of the third and fourth sides and extending along the third direction from the first side to the second side, and an indent extending along the second direction into one of the fifth and sixth sides and extending along the third direction from the first side to the second side.

20. The electronic device of claim 19, comprising one of a pair of protrusions and a pair of indents, wherein:
the pair of protrusions includes a first protrusion extending along the first direction out of the third side and extending along the third direction from the first side to the second side, and a second protrusion extending along the first direction out of the fourth side and extending along the third direction from the first side to the second side; and
the pair of indents includes a first indent extending along the second direction into the fifth side and extending along the third direction from the first side to the second side, and a second indent extending along the second direction into the sixth side and extending along the third direction from the first side to the second side.
